(19) United States
(12) Patent Application Publication
(10) Pub. No.: US 2026/0305125 A1
(43) Pub. Date: Oct. 1, 2026

(54) DISPLAY DEVICE AND ELECTRONIC DEVICE HAVING THE SAME

(71) Applicant: Samsung Display Co., Ltd., Yongin-si (KR)

(72) Inventor: Junga Lee, Yongin-si (KR)

(21) Appl. No.: 19/561,271

(22) Filed: Mar. 9, 2026

(30) Foreign Application Priority Data
Mar. 25, 2025 (KR) 10-2025-0038311

(51) Int. Cl. H10K 59/80; G02B 1/14; H10K 102/00

(52) U.S. Cl. CPC H10K 59/871; G02B 1/14; H10K 59/8792; H10K 2102/311; H10K 2102/351

(57) ABSTRACT

A display device and an electronic device are provided. The display device includes: a display panel; and a cover member on the display panel, wherein the cover member includes: a first layer on the display panel; a second layer comprising a base layer and an anti-fingerprint layer on a side surface of the base layer, the base layer comprising a resin and covering the first layer; and a third layer on the second layer.

### CROSS-REFERENCE TO RELATED APPLICATION

The present application claims priority to and the benefit of Korean Patent Application No. 10-2025-0038311, filed on Mar. 25, 2025, in the Korean Intellectual Property Office, the entire disclosure of which is incorporated by reference herein.

### BACKGROUND

### 1. Field

One or more embodiments relate to a device, and more particularly, to a display device and an electronic device including the same.

### 2. Description of the Related Art

Recently, electronic devices that are suitable for mobile use have been widely used. As portable electronic devices, tablet personal computers (PCs), as well as small-sized electronic devices, such as mobile phones, have been widely used recently.

Such a portable electronic device includes a display device capable of supporting various functions and providing a user with visual information, such as images or videos. Recently, as the size of components for driving a display device has been reduced, the relevance of the display device in an electronic device has gradually increased, and a structure bendable by a suitable angle (e.g., a predetermined angle) from a flat state has been developed.

### SUMMARY

In general, a display device may have a foldable structure. In this case, the display device should generally be as thin as possible to enable free folding and may have various structures for this purpose. One or more embodiments include a display device and an electronic device that are freely foldable and have reduced thickness.

Additional aspects will be set forth in part in the description which follows and, in part, will be apparent from the description, or may be learned by practice of embodiments of the present disclosure.

According to one or more embodiments, a display device including: a display panel; and a cover member on the display panel, wherein the cover member includes: a first layer on the display panel; a second layer including a base layer and an anti-fingerprint layer on a side surface of the base layer, the base layer including a resin and covering the first layer; and a third layer on the second layer.

According to one or more embodiments, the cover member further includes a light blocking layer on a surface of the base layer facing the display panel.

According to one or more embodiments, the light blocking layer is further on at least a portion of a surface of the first layer facing the display panel.

According to one or more embodiments, the first layer includes glass.

According to one or more embodiments, the second layer further includes a hard coating layer between the anti-fingerprint layer and the base layer.

According to one or more embodiments, a thickness of the hard coating layer is within a range of at least about 5 μm but not more than about 15 μm.

According to one or more embodiments, the second layer further includes a bonding layer between the anti-fingerprint layer and the base layer.

According to one or more embodiments, the cover member further includes an adhesive layer between the second layer and the third layer.

According to one or more embodiments, a thickness of the anti-fingerprint layer is within a range of at least about 10 nm but not more than about 40 nm.

According to one or more embodiments, the anti-fingerprint layer is between the second layer and the third layer.

According to one or more embodiments, a refractive index of the first layer and a refractive index of the base layer are same as each other.

According to one or more embodiments, a display device including: a display panel; and a cover member on the display panel, wherein the cover member includes: a first layer on the display panel; a second layer covering the first layer, wherein a first contact angle of a surface of the second layer facing the display panel and a second contact angle of a side surface of the second layer are different from each other; and a third layer on the second layer.

According to one or more embodiments, the first contact angle is less than the second contact angle.

According to one or more embodiments, the cover member further includes a light blocking layer on at least one of a surface of the first layer or the surface of the second layer facing the display panel.

According to one or more embodiments, the first layer includes glass.

According to one or more embodiments, the cover member further includes an adhesive layer between the second layer and the third layer.

According to one or more embodiments, an electronic device including: a display device; and a memory connected to the display device, wherein the display device includes: a display panel; and a cover member on the display panel, wherein the cover member includes: a first layer on the display panel; a second layer including a base layer and an anti-fingerprint layer on a side surface of the base layer, the base layer including a resin and covering the first layer; and a third layer on the second layer.

According to one or more embodiments, the cover member further includes a light blocking layer on a surface of the base layer facing the display panel.

According to one or more embodiments, the second layer further includes a hard coating layer between the anti-fingerprint layer and the base layer.

According to one or more embodiments, the second layer further includes a bonding layer between the anti-fingerprint layer and the base layer.

Other aspects and features of embodiments of the present disclosure other than those described above will become apparent from the following detailed description of the drawings, claims and their equivalents.

### BRIEF DESCRIPTION OF THE DRAWINGS

The above and other aspects and features of certain embodiments of the present disclosure will be more apparent from the following description taken in conjunction with the accompanying drawings, in which:

FIG. 1A is a perspective view schematically showing an electronic device according to one or more embodiments;

FIG. 1B is a perspective view schematically showing an electronic device in a folded state according to one or more embodiments;

FIG. 1C is a cross-sectional view schematically showing a display device according to one or more embodiments;

FIG. 1D is a cross-sectional view schematically showing a display device according to one or more embodiments;

FIG. 2A is a perspective view schematically showing an electronic device according to one or more embodiments;

FIG. 2B is a cross-sectional view schematically showing a display device according to one or more embodiments;

FIGS. 3A – 3C are each an enlarged cross-sectional view schematically showing an area AR of FIGS. 1C, 1D and 2B, respectively;

FIG. 4A is a plan view schematically showing a display panel of the display device of FIGS. 1A and 2A;

FIG. 4B is a side view schematically illustrating a portion of the display device of FIG. 4A;

FIG. 5 is a plan view schematically showing a display panel of the display device of FIGS. 1A and 2A;

FIG. 6 is an equivalent circuit diagram of one sub-pixel arranged in a display area of the display panel of FIG. 5;

FIG. 7 is a cross-sectional view schematically illustrating a portion of a display area of the display panel of FIG. 5;

FIG. 8 is a block diagram of an electronic device according to one or more embodiments; and

FIGS. 9 – 11 are schematic views of electronic devices according to various embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects and features of embodiments of the present description. As used herein, the term "and/or" includes any and all combinations of one or more of the associated listed items. Throughout the present disclosure, the expression "at least one of a, b or c" indicates only a, only b, only c, both a and b, both a and c, both b and c, all of a, b, and c, or variations thereof.

As the present disclosure allows for various changes and numerous embodiments, particular embodiments will be illustrated in the drawings and described in detail in the written description. The attached drawings for illustrating one or more embodiments are referred to in order to gain a sufficient understanding, the merits thereof, and the objectives accomplished by the implementation. However, embodiments may have different forms and should not be construed as being limited to the descriptions set forth herein.

Embodiments of the present disclosure will be described below in more detail with reference to the accompanying drawings. Those components that are the same or are in correspondence are rendered the same reference numeral regardless of the figure number, and redundant explanations are omitted.

While terms such as "first," "second," etc., may be used to describe various components, such components are not be limited to the above terms. The above terms are used only to distinguish one component from another.

An expression used in the singular encompasses the expression of the plural, unless it has a clearly different meaning in the context.

In the following embodiment, it will be further understood that the terms "comprise" and/or "have" used herein specify the presence of stated features or components, but do not preclude the presence or addition of one or more other features or components.

It will be understood that when a layer, region, or component is referred to as being "formed on" another layer, region, or component, it may be directly or indirectly formed on the other layer, region, or component. That is, for example, intervening layers, regions, or components may be present.

Sizes of components in the drawings may be exaggerated for convenience of explanation. In other words, because sizes and thicknesses of components in the drawings are arbitrarily illustrated for convenience of explanation, the following embodiments are not limited thereto.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure are described with reference to the drawings.

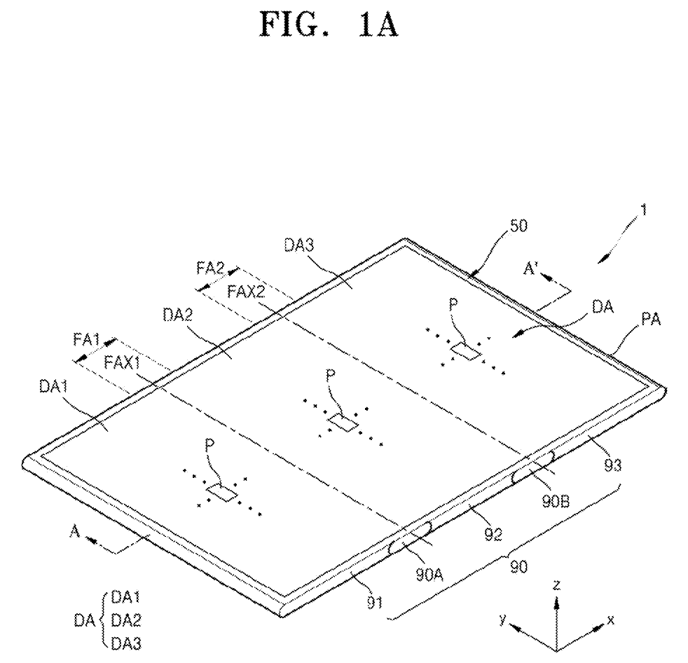

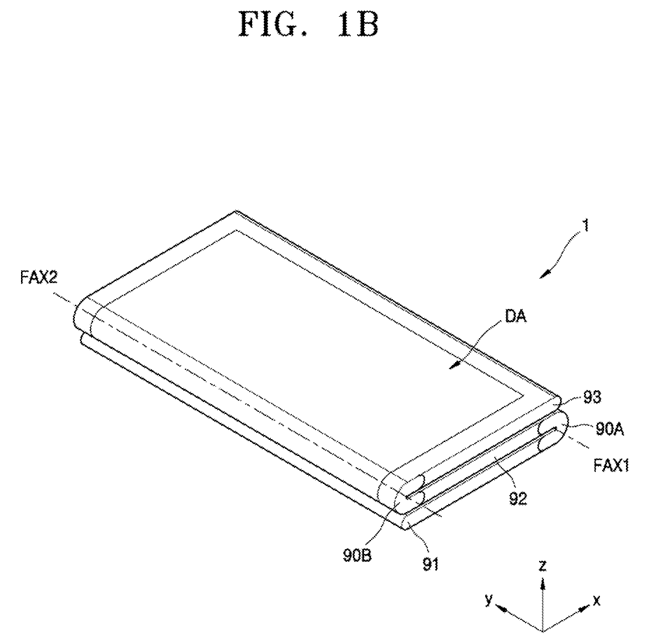

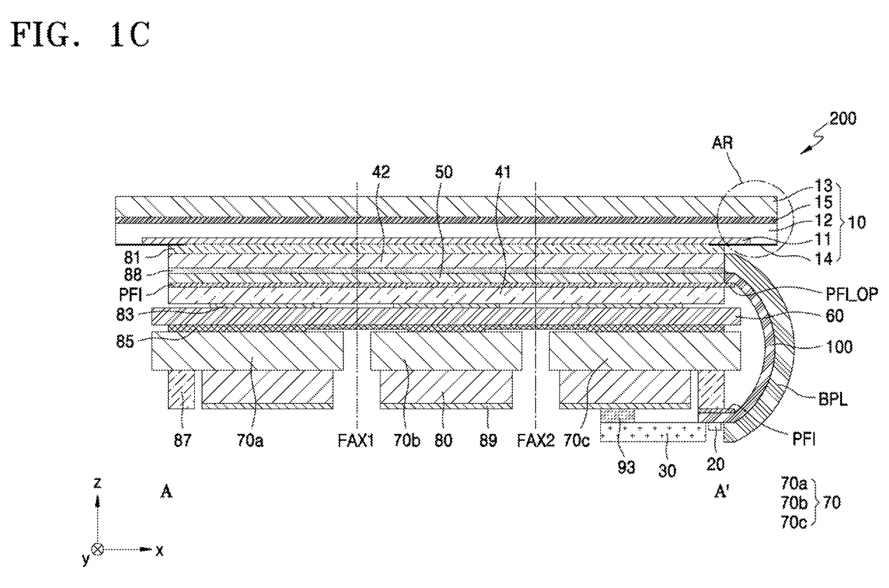

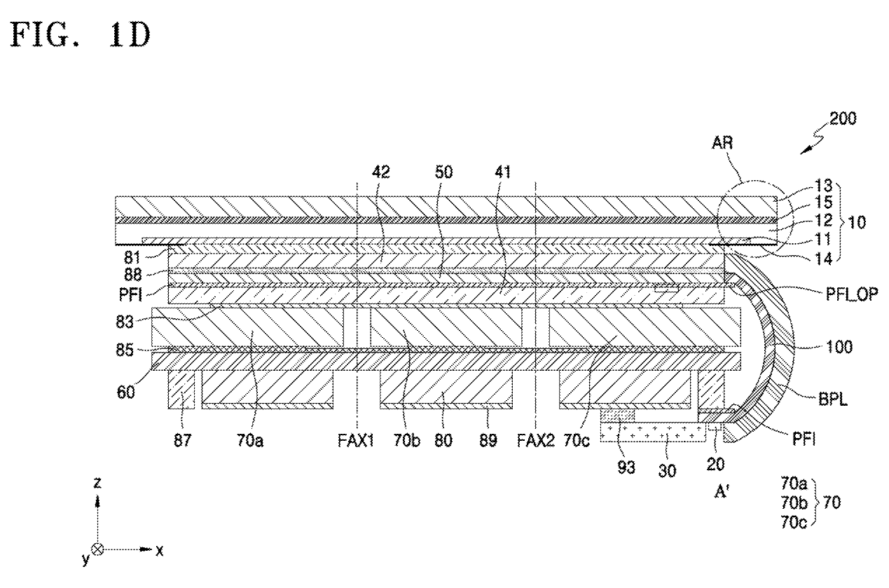

FIG. 1A is a perspective view schematically showing an electronic device according to one or more embodiments. FIG. 1B is a perspective view schematically showing an electronic device in a folded state according to one or more embodiments. In detail, FIG. 1A is a perspective view showing an electronic device 1 in an unfolded state, and FIG. 1B is a perspective view showing the electronic device 1 in a folded state.

Referring to FIGS. 1A and 1B, the electronic device 1 may display video and/or still images and may be a portable electronic device, such as a mobile phone, a smartphone, a tablet personal computer (PC), a mobile communication terminal, an electronic notebook, an electronic book, a portable multimedia player (PMP), a navigation terminal, an ultra-mobile PC (UMPC), etc., and also may be used as a display screen in various products, such as a television, a laptop computer, a monitor, a billboard, an Internet of Things (IoT) device, etc. Also, the electronic device 1 may be a wearable device, such as a smart watch, a watch phone, a glasses-type display, and/or a head mounted display (HMD). In addition, the electronic device 1 may be used as a dashboard of a vehicle, a center information display in a center fascia or dashboard of a vehicle, a rear-view mirror display that replaces a side-view mirror of a vehicle, and a display in a rear side of a front seat as entertainment for the back seat in a vehicle.

The electronic device 1 may include a display panel 50 and a lower cover 90. The display panel 50 may include a display area DA whereon images are displayed and a peripheral area PA around the display area DA along an edge or a periphery of the display area DA. Sub-pixels P, each including a display element, may be arranged in the display area DA. A plurality of sub-pixels P may be provided and may be arranged to be spaced (e.g., spaced apart) from one another. Some of the plurality of sub-pixels P, some other of the plurality of sub-pixels P, and another of the plurality of sub-pixels P may emit light of different colors. The electronic device 1 may provide images by using light emitted from the sub-pixels P in the display area DA. The peripheral area PA may be a non-display area in which the sub-pixels P are not arranged.

The display area DA may include a first display area DA1, a second display area DA2, and a third display area DA3. The sub-pixels P may be arranged in each of the first display area DA1, the second display area DA2, and the third display area DA3. The electronic device 1 may provide images via the sub-pixels P arranged in the first display area DA1, the second display area DA2, and the third display area DA3. The first display area DA1, the second display area DA2, and the third display area DA3 may be surrounded by the peripheral area PA.

The display panel 50 may display (output) information processed by the electronic device 1. For example, the display panel 50 may display information about an execution screen of an application executed on the electronic device 1 or user interface (UI) or graphical user interface (GUI) information according to the information on the execution screen. The display panel 50 may include a display layer for displaying an image and a touchscreen layer for sensing a touch input from a user. As such, the display panel 50 may function as an input device for providing an input interface between the electronic device 1 and the user, and at the same time, may function as an output unit for providing an output interface between the electronic device 1 and the user.

Hereinafter, according to one or more embodiments, although the display panel 50 is described as being an organic light-emitting display panel, the present disclosure is not limited thereto. In another embodiment, the display panel 50 may include an inorganic light-emitting display panel (or an inorganic light emitting display or an inorganic electroluminescent (EL) display), or a quantum dot light-emitting display panel. For example, an emission layer of a display element included in the display panel 50 may include an organic material, an inorganic material, quantum dots, an organic material and quantum dots, or an inorganic material and quantum dots.

In one or more embodiments, the display panel 50 may be a flexible display panel that may be easily curved, folded, and/or rolled. For example, the display panel 50 may include a foldable display panel, a curved display panel having a curved display surface, a bendable display panel having a bendable region other than the display surface, a rollable display panel that is rollable and spreadable, and a stretchable display panel. In one or more embodiments, the display panel 50 may include a rigid display panel that is rigid and not easily bendable.

In one or more embodiments, the display panel 50 may have a first folding axis FAX1 and a second folding axis FAX2. The display panel 50 may be folded about the first folding axis FAX1 and the second folding axis FAX2.

The first display area DA1 and the second display area DA2 may be defined by the first folding axis FAX1 therebetween. Also, the second display area DA2 and the third display area DA3 may be defined by the second folding axis FAX2 therebetween.

The lower cover 90 may form an exterior of a bottom surface of the electronic device 1. The lower cover 90 may include plastic, metal, or both plastic and metal. The lower cover 90 may include a first lower cover part 91, a second lower cover part 92, and a third lower cover part 93 supporting the display panel 50. The lower cover 90 may be folded about the first folding axis FAX1 between the first lower cover part 91 and the second lower cover part 92. Also, the lower cover 90 may be folded about the second folding axis FAX2 between the second lower cover part 92 and the third lower cover part 93.

In one or more embodiments, a first hinge portion 90A may be provided between the first lower cover part 91 and the second lower cover part 92, and a second hinge portion 90B may be provided between the second lower cover part 92 and the third lower cover part 93.

In one or more embodiments, the first display area DA1 and the second display area DA2 may be folded to face each other based on the first folding axis FAX1. That is, the first lower cover part 91 and the second lower cover part 92 may be folded to face each other based on the first folding axis FAX1. In one or more embodiments, the first display area DA1 and the second display area DA2 may be folded based on the first folding axis FAX1 but not to face each other.

In one or more embodiments, the second display area DA2 and the third display area DA3 may be folded based on the second folding axis FAX2 but not to face each other. That is, the second lower cover part 92 and the third lower cover part 93 may be folded to face away from each other based on the second folding axis FAX2. In one or more embodiments, the second display area DA2 and the third display area DA3 may be folded to face each other based on the second folding axis FAX2.

In one or more embodiments, when the first display area DA1 and the second display area DA2 are folded to face each other, that is, for an in-folding type, a curvature of a folded portion may be 5R or less. Alternatively, when the first display area DA1 and the second display area DA2 are folded to face each other, that is, for an in-folding type, a curvature of a folded portion may be 3R, 1R, or less.

In one or more embodiments, when the second display area DA2 and the third display area DA3 are folded not to face each other, that is, for an out-folding type, a curvature of the folded portion may be 5R or less. Alternatively, when the second display area DA2 and the third display area DA3 are folded not to face each other, that is, for an out-folding type, a curvature of the folded portion may be 4R or less. Here, R may be 1 mm.

FIG. 1C is a cross-sectional view schematically showing a display device according to one or more embodiments. FIG. 1C is a cross-sectional view taken along the line A-A' of FIG. 1A.

Referring to FIG. 1C, a display device 200 may include a cover member 10, a data driver 20, a display circuit board 30, a panel protective member 41, a functional layer 42, a display panel 50, a reinforcing member 60, a digitizer 70, a cushion layer 80, a first adhesive member 81, a second adhesive member 83, a third adhesive member 85, a fourth adhesive member 87, and a fifth adhesive member 88.

The cover member 10 may be disposed on the display panel 50. In one or more embodiments, the cover member 10 may cover an upper portion of the display panel 50. As such, the cover member 10 may protect an upper surface of the display panel 50.

In one or more embodiments, the cover member 10 may include a light-transmitting cover portion and a light-shielding cover portion, the light-transmitting cover portion corresponding to the display panel 50 and the light-shielding cover portion corresponding to the other area than the display panel 50. The light-shielding cover portion may include an opaque material that shields the display panel 50 from light. The light-shielding cover portion may include a pattern that a user may see when no image is displayed.

In one or more embodiments, the cover member 10 includes a first layer 11, a second layer 12, and a third layer 13. In one or more embodiments, the first layer 11 may include a transparent material. The first layer 11 may include glass. In another embodiment, the first layer 11 may include glass, and synthetic resin including a transparent material, etc. The first layer 11 may include at least one layer. The first layer 11 may have a plate shape. The first layer 11 may be fixed with the functional layer 42 by using the first adhesive member 81.

The second layer 12 may cover a surface of the first layer 11, and the first layer 11 may be inside the second layer 12. Here, the second layer 12 may include a resin and may be completely bonded to the first layer 11. The second layer 12 may completely cover a side surface of the first layer 11 and a surface of the first layer 11 facing the third layer 13.

In one or more embodiments, the third layer 13 may be disposed on an upper surface of the first layer 11, on the second layer 12, so as to prevent or reduce scratches on the first layer 11.

The cover member 10 may include a light blocking layer 14 on a surface of the second layer 12. In one or more embodiments, the light blocking layer 14 may be arranged at an edge of the second layer 12. The light blocking layer 14 may include black ink. The light blocking layer 14 may be not only on a portion of the second layer 12, but also on at least a portion of the surface of the first layer 11. At least a portion of the light blocking layer 14 may be inside the first adhesive member 81.

The cover member 10 may further include an adhesive layer 15 between the second layer 12 and the third layer 13. The adhesive layer 15 may be a transparent adhesive material, such as a pressure sensitive adhesive (PSA).

The display panel 50 may be disposed below the cover member 10. The display panel 50 may be connected to the display circuit board 30. In one or more embodiments, the data driver 20 and a touch sensor diver may be on the display circuit board 30. In another embodiment, the data driver 20 may be on a substrate 100 of the display panel 50, and the touch sensor deriver may be on the display circuit board 30. The substrate 100 of the display panel 50 may be at least partially bent. Here, a bending protective layer BPL may be arranged on the bent portion of the substrate 100 in order to prevent cracks in the substrate 100. The bending protective layer BPL may include a polymer resin, such as polyethylene terephthalate (PET), polyimide (PI), etc.

The bending protective layer BPL may be arranged to shield a bending region of the display panel 50. Here, one end of the bending protective layer BPL may be in contact with an end of the functional layer 42 on a cross-section.

In one or more embodiments, the functional layer 42 may be disposed on the display panel 50, and the panel protective member 41 may be disposed under the display panel 50. Here, the functional layer 42 may be between the first layer 11 and the display panel 50. Also, a touchscreen layer, through which a touch signal input is received from a user, may be provided on the display panel 50.

In one or more embodiments, the functional layer 42 may be disposed on the touchscreen layer. The functional layer 42 may include an anti-reflection layer. The anti-reflection layer may reduce a reflectivity of light (external light) incident through the display device 200 from outside.

In one or more embodiments, the anti-reflection layer may include a polarization film. The polarization film may include a linear polarization plate and a phase retardation film, such as a quarter-wave (λ/4) plate. The phase retardation film may be on the touchscreen layer, and the linear polarization plate may be on the phase retardation film.

In one or more embodiments, the anti-reflection layer may include a filter layer including a black matrix and color filters. The color filters may be arranged by taking into account a color of light emitted from each of sub-pixels in the display device 200. For example, the filter layer may include a red, green, or blue color filter. In this case, the display panel 50 may include a filter layer. The filter layer may be disposed on a touchscreen layer of the display panel 50 without using an additional adhesive layer.

In one or more embodiments, the anti-reflection layer may include a destructive interference structure. The destructive interference structure may include a first reflective layer and a second reflective layer arranged on different layers. First reflected light and second reflected light that are respectively reflected by the first reflective layer and the second reflective layer may destructively interfere with each other, and accordingly, a reflectivity of external light may be reduced.

In one or more embodiments, the functional layer 42 may further include a shock absorbing layer. Here, the shock absorbing layer may protect structures, such as the display panel thereunder, against external shock. In one or more embodiments, the shock absorbing layer may include a polymer film. The polymer film may include, for example, at least one selected from polyethylene terephthalate (PET), polyethylene naphthalate (PEN), polyether sulfone (PES), polyimide (PI), polyarylate (PAR), polycarbonate (PC), polymethyl methacrylate (PMMA), or cyclo olefin copolymer (COC).

In one or more embodiments, the functional layer 42 may include an anti-reflection layer and a shock absorbing layer. Here, the anti-reflection layer and the shock absorbing layer may be sequentially stacked on the display panel 50.

The functional layer 42 may determine positions of the ends of the bending protective layer BPL. That is, when forming the bending protective layer BPL, the bending protective layer BPL may be formed in the form of a resin and may be supplied onto the substrate 100 of the display panel 50. Here, because the bending protective layer BPL has flowability, the bending protective layer BPL may move in various directions on the display panel 50 without staying at a certain position on the display panel 50. However, when the functional layer 42 is disposed on the display panel 50, ends of the functional layer 42 may prevent the bending protective layer BPL from entering the region of the display panel 50, on which the functional layer 42 is disposed, and may limit the region on which the bending protective layer BPL flows. Therefore, the bending protective layer BPL may be arranged only in the peripheral area of the display panel 50, and may not be arranged in the display area DA.

The fifth adhesive member 88 may be located between the functional layer 42 and the display panel 50. The fifth adhesive member 88 may adhere the functional layer 42 to the display panel 50. Here, the fifth adhesive member 88 may be a pressure sensitive adhesive (PSA) or a transparent adhesive layer, such as an optically clear adhesive (OCA).

The cover member 10 may be disposed on the functional layer 42. The cover member 10 may be adhered onto the functional layer 42 via the first adhesive member 81. In one or more embodiments, the first adhesive member 81 may be a PSA or a transparent adhesive layer, such as an OCA.

In one or more embodiments, a protective film PFI may be disposed under the display panel 50. Here, the protective film PFI may absorb the impact applied from the outside of the display device 200. In this case, the protective film PFI may include an opening area PFI_OP corresponding to a bending area of the display panel 50, as described below. Here, a width of the opening area PFI_OP may be less than that of the bending area of the display panel 50.

The panel protective member 41 may be disposed under the protective film PFI. The panel protective member 41 may be adhered to a lower portion of the protective film PFI via a PSA. However, the present disclosure is not limited thereto.

In one or more embodiments, a digitizer 70 may be disposed below the display panel 50. Here, the digitizer 70 includes a pattern layer so as to sense a signal input from an external electronic pen, etc. In particular, the digitizer 70 may sense an intensity, a direction, etc. of the signal input from the electronic pen, etc. The digitizer 70 may be electrically connected to a main circuit board that is separately provided. However, the present disclosure is not limited thereto.

The digitizer 70 according to one or more embodiments may include a first portion 70a, a second portion 70b, and a third portion 70c. In one or more embodiments, the first portion 70a of the digitizer 70 may at least partially overlap the first display area DA1, and the second portion 70b of the digitizer 70 may at least partially overlap the second display area DA2. The third portion 70c of the digitizer 70 may at least partially overlap the third display area DA3. Also, the first portion 70a and the second portion 70b of the digitizer 70 may at least partially overlap a first folding area FA1, and the second portion 70b and the third portion 70c of the digitizer 70 may at least partially overlap a second folding area FA2.

In one or more embodiments, the first portion 70a and the second portion 70b of the digitizer 70 may be spaced (e.g., spaced apart) from each other in a first direction (x-direction) with the first folding axis FAX1 therebetween. Also, the second portion 70b and the third portion 70c of the digitizer 70 may be spaced (e.g., spaced apart) from each other in the first direction (x-direction) with the second folding axis FAX2 therebetween. That is, the digitizer 70 may be provided in a separation type, not in an integrated type. Because the digitizer 70 is provided to have a separation type structure, generation of cracks in the digitizer 70 arranged in the first folding area FA1 and the second folding area FA2 may be prevented or reduced.

In the above example, the digitizer 70 provided in a separation type is formed to at least partially overlap the first folding area FA1 and the second folding area FA2, and thus, the first folding area FA1 and the second folding area FA2 may also receive a signal input, and user convenience may be improved.

In one or more embodiments, the reinforcing member 60 may be arranged between the display panel 50 and the digitizer 70. In one or more embodiments, the reinforcing member 60 may be disposed below the display panel 50 and support the display panel 50.

The reinforcing member 60 may have various structures depending on whether the display device 200 is folded and a folding type. For example, when the display device 200 is not folded, the reinforcing member 60 may have a shape that is not variable.

In one or more embodiments, the reinforcing member 60 may include at least one of glass, plastic, or metal. In one or more embodiments, the reinforcing member 60 may include glass and plastic, glass and metal, plastic and metal, or all of glass, plastic, and metal.

Referring back to FIG. 1C, in one or more embodiments, the reinforcing member 60 may be adhered to the panel protective member 41 via the second adhesive member 83. In one or more embodiments, the second adhesive member 83 may be a PSA or a transparent adhesive member, such as an OCA film.

In one or more embodiments, the reinforcing member 60 and the digitizer 70 may be adhered via the third adhesive member 85. In one or more embodiments, the third adhesive member 85 may include a PSA, an OCA film, or a thermoplastic polyurethane (TPU).

In one or more embodiments, the third adhesive member 85 may be located under the reinforcing member 60.

In one or more embodiments, a cushion layer 80 may be disposed under the digitizer 70. In one or more embodiments, the cushion layer 80 may prevent or reduce damage to the digitizer 70 disposed thereon from external shock.

In one or more embodiments, an insulating film 89 may be disposed under the cushion layer 80. Because the cushion layer 80 includes a sticky material, the cushion layer 80 may be attached to another member and may interfere with the folding of the electronic device 1. Therefore, because the insulating film 89 is attached to the lower portion of the cushion layer 80, attaching of the cushion layer 80 to another member may be prevented or reduced so that the electronic device 1 may be easily folded.

In one or more embodiments, the fourth adhesive member 87 may be disposed under the digitizer 70. In one or more embodiments, the fourth adhesive member 87 may include a PSA or an OCA film. However, the present disclosure is not limited thereto. In one or more embodiments, the digitizer 70 may be connected to a main circuit board that is separately provided, via the fourth adhesive member 87. However, the present disclosure is not limited thereto.

The above main circuit board may be provided separately from or integrally with the display circuit board 30. Here, when the main circuit board and the display circuit board 30 are separately provided to be distinguished from each other, the main circuit board and the display circuit board 30 may be connected to each other via a cable, etc. However, for convenience of description, an example in which the main circuit board is separately provided from the display circuit board 30 is described in detail below.

The main circuit board may include a main processor, a camera device, a main connector, and components. The main processor may include an integrated circuit (IC). The camera device may be both on an upper surface and a lower surface of the main circuit board, and each of the main processor and the main connector may be on one of the upper and lower surfaces of the main circuit board.

The main processor may control all functions of the display device 200. For example, the main processor may output digital video data to the data driver 20 via the display circuit board 30 so that the display panel 50 displays an image. Also, the main processor may receive an input of sensing data from the touch sensor driver. The main processor may determine whether there is a touch by the user according to the sensing data, and perform an operation corresponding to a direct touch or a proximity touch by the user. For example, the main processor may calculate a touch coordinate of the user by analyzing the sensing data, and execute an application or perform an operation indicated by an icon touched by the user. The main processor may include an application processor, a central processing unit, or a system chip.

The camera device may process image frames of a still image and/or a moving picture obtained by an image sensor in a camera mode, and output the processed result to the main processor. The camera device may include at least one of a camera sensor (e.g., charge coupled device (CCD), complementary metal oxide semiconductor (CMOS), etc.), a photo sensor (or image sensor), or a laser sensor. The camera device may be connected to the image sensor from among components overlapping a component area and process an image input to the image sensor.

A cable after passing through a cable hole of a bracket may be connected to the main connector, and thus, the main circuit board may be electrically connected to the display circuit board 30.

The main circuit board may further include, in addition to the main processor, the camera device, and the main connector, at least one wireless communication unit, at least one input unit, at least one sensor unit, at least one output unit, at least one interface unit, a memory, and a power supplier.

The wireless communication unit may include at least one of a broadcast receiving module, a mobile communication module, a near field communication module, or a position information module.

The broadcast receiving module receives a broadcast signal and/or broadcast-related information from an external broadcast management server via a broadcast channel. The broadcast channel may include satellite channels and terrestrial channels.

The mobile communication module may transmit/receive a wireless signal to/from at least one of a base station, an external terminal, or a server on a mobile communication network established according to technology standards or communication methods for mobile communication (e.g., global system for mobile communication (GSM), code division multi access (CDMA), CDMA2000, enhanced voice-data optimized or enhanced voice-data only (EV-DO), wideband CDMA (WCDMA), high speed downlink packet access (HSDPA), high speed uplink packet access (HSUPA), long term evolution (LTE), long term evolution-advanced (LED-A), etc.). The wireless signal may include a voice call signal, a video call signal, or various types of data according to transmission/reception of texts/multimedia messages.

A wireless Internet module may denote a module for accessing wireless Internet. The wireless Internet module may be configured to transmit/receive a wireless signal in a communication network according to wireless Internet technologies. The wireless Internet technology may include, for example, wireless local area network (LAN) (WLAN), wireless-fidelity (Wi-Fi), Wi-Fi direct, digital living network alliance (DLNA), etc.

A short-range communication module may support short-range communication by using at least one selected from Bluetooth, Radio Frequency Identification (RFID), Infrared Data Association (IrDA), Ultra-Wideband (UWB), ZigBee, Near Field Communication (NFC), Wi-Fi, Wi-Fi Direct, or Wireless Universal Serial Bus (USB). The short-range communication module may support, via wireless area networks, wireless communication between the display device 200 and a wireless communication system, between the display device 200 and another electronic device, or between the display device 200 and a network in which another electronic device (or an external server) is located. The wireless area network may include a wireless personal area network. Another electronic device may include a wearable device capable of exchanging data (or linkable) with the display device 200.

The position information module is for obtaining a location of the display device 200 (or a current location), and examples of the position information module may include a global positioning system (GPS) module or Wi-Fi module. For example, the display device 200 may obtain the location of the display device 200 by using a signal provided from a GPS satellite, in a case of using the GPS module. Also, the display device 200 may obtain the location of the display device 200, based on information of a wireless access point (AP) transmitting or receiving a wireless signal to/from the Wi-Fi module, in a case of using the Wi-Fi module. The position information module is used to obtain the location of the display device 200 (or a current location) and not limited to a module for directly calculating or obtaining the location of the display device 200.

The input unit may include an image input unit, such as a camera device for inputting image signals, a sound input unit, such as a microphone for inputting sound signals, and an input device for receiving input of information from the user.

The camera device may process image frames, such as still images, moving pictures, etc. obtained by an image sensor in a video call mode or a photographing mode. The processed image frame may be displayed on the display panel 50 or stored in a memory.

The microphone may process a sound signal from outside as electrical voice data. The voice data may be variously used according to the function (or application being executed) performed by the display device 200. The microphone may use various noise canceling algorithms for canceling noise generated when receiving the sound signal from the outside.

The main processor may control operations of the display device 200 so as to correspond to information input through the input device. The input device may include a mechanical input unit, such as a button located on a rear surface or a side surface of the display device 200, a dome switch, a jog-wheel, a jog switch, etc. or a touch input unit. The touch input unit may include a touchscreen layer of the display panel 50.

The sensor unit may include one or more sensors that sense at least one of information in the display device 200, peripheral environment information of the display device 200, or user information, and generate a sensing signal corresponding to the sensed information. The main processor may control driving or operation of the display device 200, may process data, or perform functions or operations regarding an application installed on the display device 200, based on the sensing signal. The sensor unit may include at least one selected from a proximity sensor, an illumination sensor, an acceleration sensor, a magnetic sensor, a G-sensor, a gyroscope sensor, a motion sensor, an RGB sensor, an infrared ray (IR) sensor, a finger scan sensor, an ultrasonic sensor, an optical sensor, a battery gauge, an environmental sensor (e.g., a barometer, a hydrometer, a thermometer, a radiation detection sensor, a heat detection sensor, a gas detection sensor, etc.), or a chemical sensor (e.g., an electronic nose, a healthcare sensor, a biometric sensor, etc.).

The proximity sensor denotes a sensor for sensing an existence of an object approaching a suitable detect surface (e.g., a predetermined detect surface) or an object around the detect surface by using an electromagnetic field or an infrared ray, without a physical contact. Examples of the proximity sensor may include a transmission-type photoelectric sensor, a direct reflective photoelectric sensor, a mirror reflective photoelectric sensor, a radio frequency oscillation-type proximity sensor, a capacitive-type proximity sensor, a magnetic-type proximity sensor, an infrared ray proximity sensor, etc. The proximity sensor may sense a proximity touch pattern, such as a proximity touch distance, a proximity touch direction, a proximity touch speed, a proximity touch time, a proximity touch position, and a proximity touch movement, etc., as well as the proximity touch. The main processor may process data (or information) corresponding to the proximate touch operation or the proximate touch pattern sensed by the proximity sensor, and control visual information corresponding to processed data to be displayed on the display panel 50.

The ultrasonic sensor may recognize position information of an object. The main processor may calculate a position of an object through information sensed by the optical sensor and a plurality of ultrasonic sensors. Because the speed of light and the speed of ultrasonic waves are different from each other, the position of the object may be calculated by using a time taken for the light to reach the optical sensor and a time for the ultrasonic wave to reach the ultrasound sensor.

The output unit generates an output related to visual, auditory, or tactile sense, and may include at least one selected from among the display panel 50, a sound output unit, a haptic module, and an optical output unit.

The sound output unit may output sound data received from the wireless communication unit or stored in the memory in a call signal reception, a call mode or a recording mode, a voice recognition mode, a broadcast reception mode, etc. The sound output unit outputs a sound signal related to the function executed on the display device 200 (e.g., a call signal reception sound, a message reception sound, etc.). The sound output unit may include a receiver and a speaker. At least one of the receiver or the speaker may be a sound generation device that is attached to a lower portion of the display panel 50 to vibrate the display panel 50 and output sound. The sound generation device may include a piezoelectric element or a piezoelectric actuator that contracts and expands according to an electric signal, or an exciter that generates a magnetic force by using a voice coil to vibrate the display panel 50.

The haptic module generates various tactile effects that the user may feel. The haptic module may provide the user with the vibration as the tactile effect. An intensity and pattern of the vibrations generated by the haptic module may be controlled by a selection of the user or a setting of the main processor. For example, the haptic module may synthesize and output different vibrations or sequentially output the different vibrations. The haptic module may generate various tactile effects, for example, arrangement of pins that move vertically to contact the skin surface, air injection force or air suction force through an injection port or a suction port, grazing on the skin surface, contact of an electrode, effects caused by stimulation of electromagnetic force, and effects caused by reproducing cooling and warming feeling by using endothermic or exothermic elements. The haptic module may be implemented such that the user may feel the tactile effect through muscle sensation, such as a finger, an arm, etc., as well as the tactile effect through direct contact.

The optical output unit outputs a signal for notifying an occurrence of an event by using the light from a light source. Examples of the event occurring on the display device 200 may include a message reception, a call signal reception, a missed call, an alarm, schedule notification, email reception, information reception through an application, etc. The signal output from the optical output unit may be realized when the display device 200 emits light of a single color or a plurality of colors through a front surface or a rear surface thereof. The signal output may be terminated when the display device 200 senses that the user identifies the event.

The interface unit acts as a path to various external devices connected to the display device 200. The interface unit may include at least one selected from a wired/wireless headset port, an external charger port, a wired/wireless data port, a memory card port, a port for connecting a device including an identification module, an audio input/output (I/O) port, a video I/O port, or an earphones port. The display device 200 may perform an appropriate control regarding an external device connected thereto, in response to the connection of the external device to the interface unit.

The memory stores data supporting various functions of the display device 200. The memory may store a plurality of application programs driven on the display device 200, data for operating the display device 200, and instructions. At least some of the plurality of application programs may be downloaded from an external server via wireless communication. The memory may store an application for operating the main processor and may temporarily store input/output data, e.g., data, such as a phone book, messages, still images, videos, etc. Also, the memory may store haptic data for various patterns of vibrations provided to the haptic module and sound data about various sounds provided to the sound output unit. The memory may include at least one type of storage medium selected from a flash memory type, a hard disk type, a solid state disk (SSD) type, a silicon disk drive (SSD) type, a multimedia card micro type, a card type (e.g., SD or XD memory, etc.), random access memory (RAM), static RAM (SRAM), read-only memory (ROM), electrically erasable programmable ROM (EEPROM), programmable ROM (PROM), magnetic memory, a magnetic disk, or an optical disk.

The power supplier supplies electric power to each of elements included in the display device 200 by receiving external and internal power, under the control by the main processor. The power supplier may include a battery. Also, the power supplier includes a connection port, and the connection port may be implemented as an example of the interface unit to which the external charger supplying the electric power for charging the battery is electrically connected. Alternatively, the power supplier may be implemented to charge the battery in a wireless manner without using the connection port. The battery may receive the electric power from an external wireless power transfer device by at least one of an inductive coupling method based on a magnetic induction phenomenon and a magnetic resonance coupling method based on an electromagnetic resonance phenomenon. The battery may be provided not to overlap the main circuit board in a third direction (z- direction). The battery may overlap the battery hole of the bracket.

FIG. 1D is a cross-sectional view schematically showing a display device according to one or more embodiments. FIG. 1D is a cross-sectional view of another example taken along the line A-A' of FIG. 1A.

Referring to FIG. 1D, the display device 200 may include the cover member 10, the panel protective member 41, the functional layer 42, the display panel 50, the protective film PFI, the reinforcing member 60, the digitizer 70, the cushion layer 80, and the insulating film 89. Here, the cover member 10, the panel protective member 41, the functional layer 42, the display panel 50, the protective film PFI, the reinforcing member 60, the digitizer 70, the cushion layer 80, the insulating film 89, and the lower cover 90 may be the same as or similar to those described above with reference to FIGS. 1A – 1C.

The digitizer 70 may be disposed below the display panel 50. In this case, the digitizer 70 may include the first portion 70a, the second portion 70b, and the third portion 70c as described above with reference to FIG. 1C.

In one or more embodiments, an additional barrier film may be arranged between the display panel 50 and the reinforcing member 60 of FIG. 1C or between the display panel 50 and the digitizer 70 of FIG. 1D. In this case, the barrier film may be arranged on the rear surface of the display panel 50 and may prevent scratches, etc. that may occur during manufacturing of the display panel 50. Here, the barrier film may include a colored polyimide film. For example, the barrier film may include an opaque yellow film, but is not limited thereto.

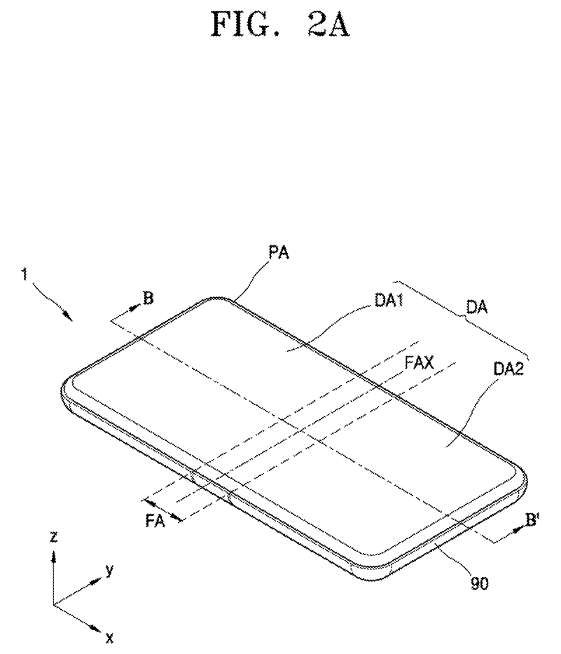

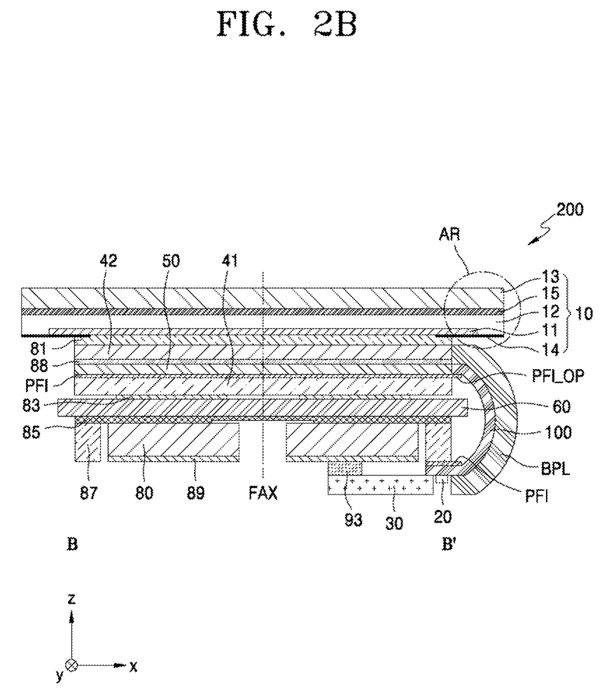

FIG. 2A is a perspective view schematically showing a display device according to one or more embodiments. FIG. 2B is a cross-sectional view schematically showing a display device according to one or more embodiments. FIG. 2B is a cross-sectional view taken along the line B-B' of FIG. 2A.

Referring to FIGS. 2A and 2B, the electronic device 1 may include the display area DA, and the peripheral area PA around the display area DA. In one or more embodiments, the electronic device 1 may include a folding area FA, and the display area DA may include a first display area DA1 and a second display area DA2 that are spaced (e.g., spaced apart) from each other with the folding area FA therebetween. Here, the display area DA, the folding area FA, and the peripheral area PA are similar to or the same as those described in FIG. 1A, and detailed descriptions thereof are omitted.

In one or more embodiments, the electronic device 1 may include the display device 200 and the lower cover 90. The display device 200 may include the cover member 10, the panel protective member 41, the functional layer 42, the display panel 50, the protective film PFI, the reinforcing member 60, the cushion layer 80, and the insulating film 89. The cover member 10, the panel protective member 41, the functional layer 42, the display panel 50, the protective film PFI, the reinforcing member 60, the cushion layer 80, the insulating film 89, and the lower cover 90 may be the same as or similar to those described above with reference to FIGS. 1A – 1D.

The cover member 10 may include the first layer 11, the second layer 12, the third layer 13, the adhesive layer 15, and the light blocking layer 14. The first layer 11, the second layer 12, the third layer 13, the adhesive layer 15, and the light blocking layer 14 may be the same as or similar to those described with reference to FIGS. 1A – 1D.

The first adhesive member 81 may be arranged between the cover member 10 and the functional layer 42, and the fifth adhesive member 88 may be arranged between the functional layer 42 and the display panel 50. The third adhesive member 85 may be arranged between the reinforcing member 60 and the cushion layer 80, and the fourth adhesive member 87 may be disposed on the third adhesive member 85. The second adhesive member 83 may be between the reinforcing member 60 and the panel protective member 41.

Hereinafter, "upper portion" denotes a direction in which the cover member 10 is located based on the display panel 50, that is, a +z direction, and "lower portion" denotes a direction in which the reinforcing member 60 is located based on the display panel 50, that is, a -z direction.

In one or more embodiments, the electronic device 1 may have a rectangular shape on a plane (e.g., in a plan view). For example, the electronic device 1 may have a rectangular plane shape having longer sides in the first direction (x-direction) and shorter sides in the second direction (y-direction) that crosses the first direction (x-direction), as shown in FIG. 2A. A corner where the longer side in the first direction (x-direction) and the shorter side in the second direction (y-direction) meet each other may be rounded to have a certain curvature or may be right-angled. The planar shape of the electronic device 1 is not limited to the rectangular shape, but may have another polygonal shape, an elliptical shape, or a non-defined shape.

In one or more embodiments, the electronic device 1 may have various shapes. For example, the electronic device 1 may have a shape that is not variable. In one or more embodiments, the electronic device 1 may be at least partially folded. In this case, the electronic device 1 may be an in-folding type in which the display area DA is folded to face each other when folding the electronic device 1, or an out-folding type in which the display area DA is exposed to outside when folding the electronic device 1. Hereinafter, for convenience of description, an example in which the electronic device 1 is an in-folding type will be described below.

In one or more embodiments, the electronic device 1 may be folded based on (or about) a folding axis FAX. In this case, when the electronic device 1 is folded based on (or about) the folding axis FAX, the size of the electronic device 1 may be reduced as compared with that when the electronic device 1 is completely unfolded.

Therefore, when the electronic device 1 is completely unfolded, a large display screen may be implemented, and when the electronic device 1 is completely folded, the size of the electronic device 1 is reduced and results in improving the portability of the electronic device 1.

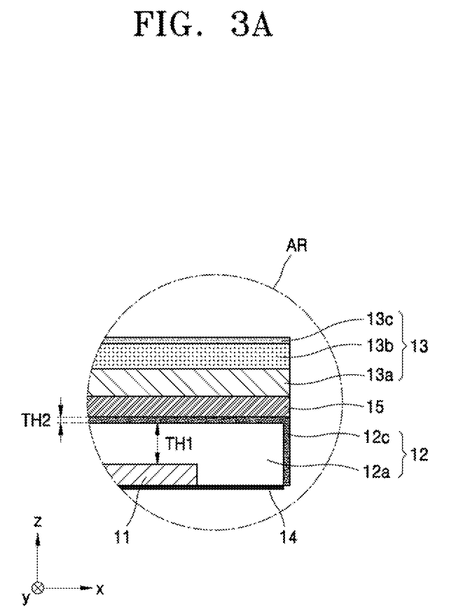

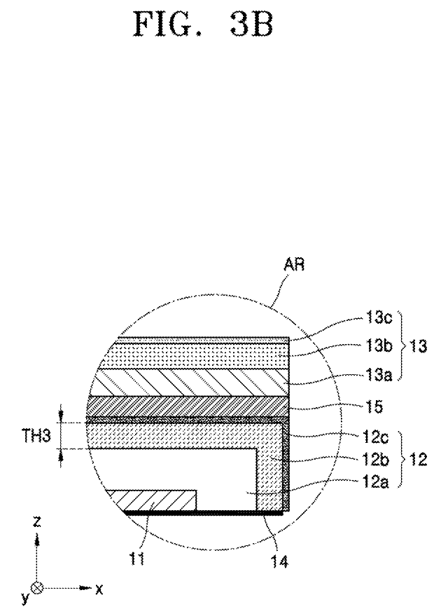

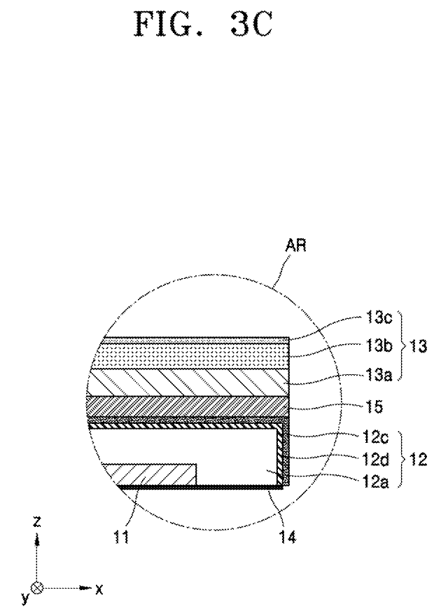

FIG. 3A – 3C are each an enlarged cross-sectional views schematically showing an area AR of the FIGS. 1C, 1D and 2B, respectively.

Referring to FIG. 3A, the cover member 10 may include the first layer 11, the second layer 12, the third layer 13, the adhesive layer 15, and the light blocking layer 14.

The second layer 12 may include a first base layer 12a covering three surfaces of the first layer 11, and a first anti-fingerprint layer 12c on the first base layer 12a.

The first base layer 12a may be formed in resin type and may be on a portion of the first layer 11. For example, the first base layer 12a may be in a form of the resin coated on the first layer 11, and completely cover a side surface of the first layer 11 and a surface of the first layer 11 facing the third layer 13. A first thickness TH1 that is a minimum thickness of the first base layer 12a may be within a range of at least about 15 μm but not more than about 50 μm. For example, a portion of the first base layer 12a that is the minimum thickness among the thickness of the first base layer 12a may be a portion where the first base layer 12a and the first layer 11 overlap each other. When the first thickness TH1 that is a minimum thickness of the first base layer 12a may be less than 15 μm, the first base layer 12a may not effectively absorb an external impact, so the first layer 11 may be damaged by the external impact. In addition, when the first thickness TH1 that is a minimum thickness of the first base layer 12a is greater than 50 μm, a path through which light emitted from the display panel 50 passes becomes too long, so the display device 200 may not provide a clear image. The first base layer 12a may have a refractive index nearly equal to that of the first layer 11. For example, the refractive index of the first base layer 12a may be within a range of at least about 1.4 but not more than about 1.5. Because the first base layer 12a has the above refractive index, light passing through the first layer 11 is not refracted in the first base layer 12a, thereby reducing distortion of the image displayed on the display panel 50.

The first anti-fingerprint layer 12c may be on a portion of a surface of the first base layer 12a. For example, the first anti-fingerprint layer 12c may be only on a side surface of the first base layer 12a. In one or more embodiments, the first anti-fingerprint layer 12c may be on the side surface of the first base layer 12a, and a surface of the first base layer 12a facing the third layer 13. Hereinafter, for convenience of explanation, a case where the first anti-fingerprint layer 12c may be on the side surface of the first base layer 12a, and the surface of the first base layer 12a facing the third layer 13 is described in detail.

The first anti-fingerprint layer 12c may be an anti-fingerprint layer including a fluorine (F) compound. The first anti-fingerprint layer 12c may reduce the light blocking layer 14 from being on the side surface of the first base layer 12a. That is, the light blocking layer 14 may be only on the side surface of the first base layer 12a where the first anti-fingerprint layer 12c is not located. At this time, a contact angle of the first base layer 12a on which the light blocking layer 14 is located may be different from the contact angle of the first anti-fingerprint layer 12c on which the light blocking layer 14 is not located. For example, the contact angle of the first base layer 12a may be smaller than a contact angle of the first anti-fingerprint layer 12c. Through this, the light blocking layer 14 may be not on the first anti-fingerprint layer 12c. In detail, when the light blocking layer 14 is arranged on the first layer 11 and the first base layer 12a, the light blocking layer 14 may be supplied in the form of ink. The light blocking layer 14 may flow to the side surface of the first base layer 12a on which the first anti-fingerprint layer 12c is located. The first anti-fingerprint layer 12c on the side surface of the first base layer 12a may prevent the light blocking layer 14 from settling on the first anti-fingerprint layer 12c. That is, the light blocking layer 14 on the first anti-fingerprint layer 12c may flow to another location where there is no first anti-fingerprint layer 12c or may be easily separated from the surface of the first anti-fingerprint layer 12c. A second thickness TH2 of the first anti-fingerprint layer 12c may be within a range of at least about 10 nm but not more than about 40 nm. When the second thickness TH2 of the first anti-fingerprint layer 12c is less than 10 nm, the first anti-fingerprint layer 12c on the side surface of the first base layer 12a may not cover the entire side surface of the first base layer 12a. In addition, when the second thickness TH2 of the first anti-fingerprint layer 12c is greater than 40 nm, light from the display panel 50 may be excessively refracted.

Accordingly, through the structure as described above, because the light blocking layer 14 is not on the side surface of the first base layer 12a, the amount of light that is blocked from among the light emitted from the display panel 50 may be reduced. In addition, the light blocking layer 14 may be placed at a set position as described above.

One surface of the third layer 13 may be exposed to the outside. That is, based on FIG. 3A, no separate member or material may be on an upper surface of the third layer 13. The third layer 13 may include a second base layer 13a, a second hard coating layer 13b, and a second anti-fingerprint layer 13c. The second base layer 13a may include polyethylene terephthalate (PET), polyethylene naphthalate (PEN), polyether sulfone (PES), and/or polyethylene (PE) film. Additionally, the second hard coating layer 13b may include an acrylic compound, an epoxy compound, an organic-inorganic composite compound, and/or a combination thereof. However, the present disclosure is not limited thereto, and the second hard coating layer 13b may include other ultraviolet-curable resins other than acrylic compounds and epoxy compounds. The second anti-fingerprint layer 13c may be identical or similar to the first anti-fingerprint layer 12c.

The second layer 12 and the third layer 13 may be adhered to each other through the adhesive layer 15. At this time, the adhesive layer 15 may be on the entire surface of the third layer 13. Through this, the adhesive layer 15 may firmly adhere the second layer 12 and the third layer 13 to each other.

Referring to FIG. 3B, the cover member 10 may include the first layer 11, the second layer 12, the third layer 13, the adhesive layer 15, and the light blocking layer 14. At this time, the second layer 12, the third layer 13, the adhesive layer 15, and the light blocking layer 14 are the same or similar to those described above, thus, a detailed description thereof is omitted.

The second layer 12 may include the first base layer 12a, a first hard coating layer 12b, and a first anti-fingerprint layer 12c. At this time, the first base layer 12a and the first anti-fingerprint layer 12c are the same or similar to those described above, thus, a detailed description thereof is omitted.

The first hard coating layer 12b may include a material identical to or similar to the second hard coating layer 13b. The first hard coating layer 12b may be between the first base layer 12a and the first anti-fingerprint layer 12c. A third thickness TH3 of the first hard coating layer 12b may be within the range of at least about 5 μm but not more than about 15 μm. When the third thickness TH3 is less than 5 μm, a layer positioned underneath the first hard coating layer 12b may not be protected from external impact. When the third thickness TH3 is greater than 15 μm, the light emitted from the display panel 50 may be refracted by the first hard coating layer 12b.

In one or more embodiments, the first hard coating layer 12b may not be on the side surface of the first base layer 12a. That is, the first hard coating layer 12b may be only between the first base layer 12a and the third layer 13. In this case, the first anti-fingerprint layer 12c may be between the first hard coating layer 12b and the third layer 13 and on the side surface of the first base layer 12a.

Referring to FIG. 3C, the cover member 10 may include the first layer 11, the second layer 12, the third layer 13, the adhesive layer 15, and the light blocking layer 14. At this time, the second layer 12, third layer 13, the adhesive layer 15, and the light blocking layer 14 are the same or similar to those described above, thus, a detailed description thereof is omitted.

The second layer 12 may include the first base layer 12a, a bonding layer 12d, and the first anti-fingerprint layer 12c. At this time, the first base layer 12a and the first anti-fingerprint layer 12c are the same or similar to those described above, thus, a detailed description thereof is omitted.

The bonding layer 12d may be between the first base layer 12a and the first anti-fingerprint layer 12c to reduce the separation of the first anti-fingerprint layer 12c from the first base layer 12a. For example, the bonding layer 12d may include silicon dioxide (SiO₂). That is, the bonding layer 12d may be on all surfaces of the first base layer 12a where the first anti-fingerprint layer 12c is located. Through this, the first anti-fingerprint layer 12c may be uniformly on the first base layer 12a.

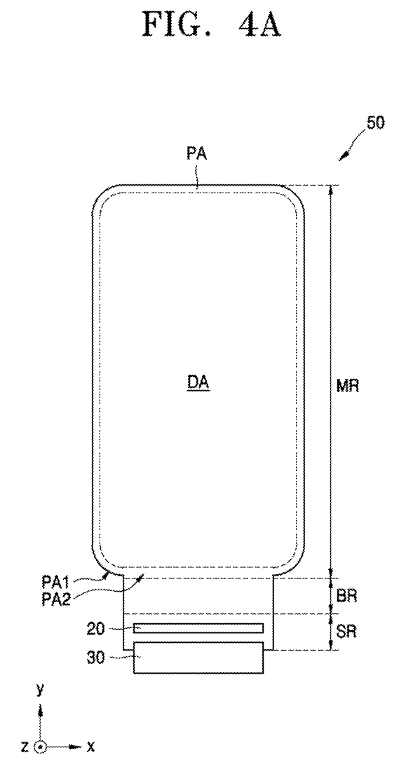

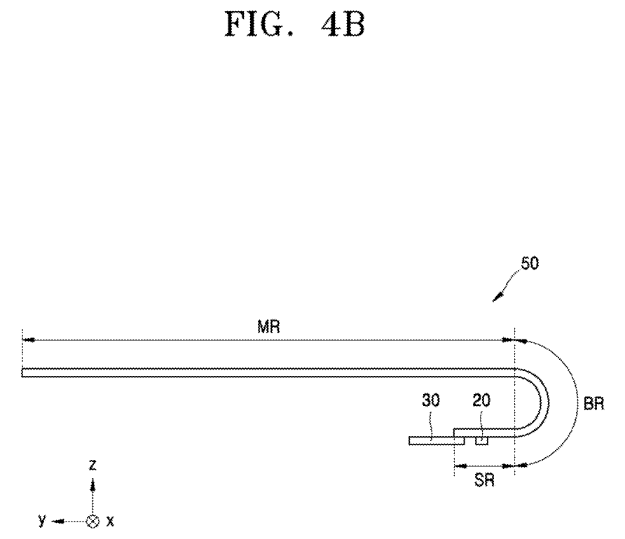

FIG. 4A is a plan view schematically showing a display panel of the display device of FIGS. 1A and 2A.

FIG. 4B is a side view (e.g., a cross-sectional view) schematically illustrating a portion of the display device of FIG. 4A. The electronic device 1 may include the display panel 50 as shown in FIGS. 4A and 4B.

Referring to FIGS. 4A and 4B, the display panel 50 may include the display area DA and the peripheral area PA outside the display area DA. The display area DA is a portion that displays an image and a plurality of sub-pixels may be arranged in the display area DA. The display area DA may have various shapes, such as a circle, an ellipse, a polygon, and a specific shape. FIG. 4A illustrates that the display area DA has an approximately rectangular shape with rounded corners.

The peripheral area PA may be arranged outside the display area DA. The peripheral area PA may include a first peripheral area PA1 around (e.g., surrounding) at least a portion of the display area DA, and a second peripheral area PA2 located at a bottom end of the display area DA and extending in a first direction (the x direction). The width of the second peripheral area PA2 in the first direction (the x direction) may be smaller than the width of the display area DA. This structure makes it easier to bend at least a portion of the second peripheral area PA2.

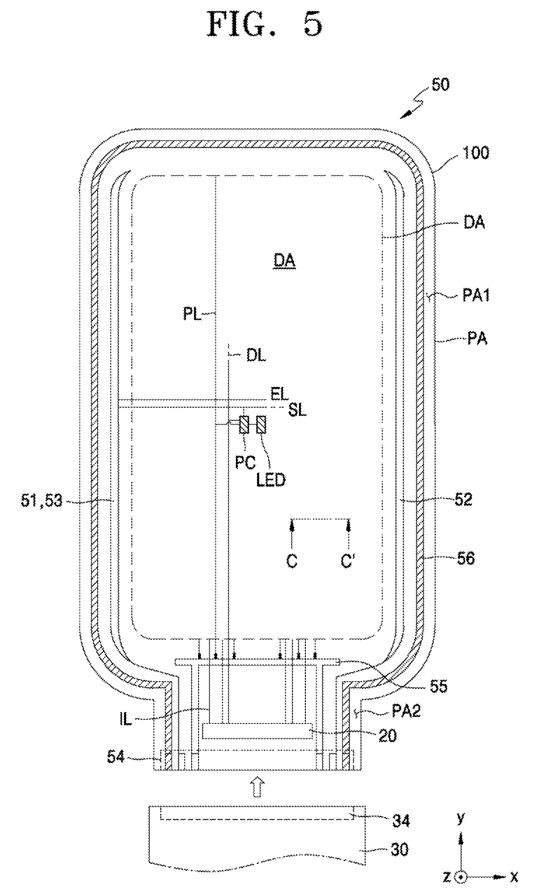

The planar shape of the display panel 50 shown in FIG. 4A may be substantially the same as the shape of the substrate 100 (e.g., see FIG. 5) included in the display panel 50. When the display panel 50 includes the display area DA and the peripheral area PA outside the display area DA, it means that the substrate 100 includes the display area DA and the peripheral area PA outside the display area DA (e.g., see FIG. 5). Hereinafter, for convenience, it is described that the substrate 100 has the display area DA and the peripheral area PA.

The display panel 50 may include a main area MR, a bending area BR outside the main area MR, and a sub-area SR spaced (e.g., spaced apart) from the main area MR with the bending area BR therebetween. The main area MR may be arranged on one side of the bending area BR, and the sub-area SR may be arranged on the other side of the bending area BR. The display panel 50 may be bent in the bending area BR as shown in FIG. 4B, and when viewed in the third direction (the z- direction), at least a portion of the sub-area SR may overlap the main area MR. FIG. 4B illustrates that the display panel 50 is bent, but the present disclosure is not limited thereto. For example, the display panel 50 may be a foldable display panel, and in this case, the display panel 50 may be bent within the display area DA around a bending axis that crosses the display area DA. If necessary, the display panel 50 may not be bent. The sub-area SR may be a non-display area.

The data driver 20 may be arranged in the sub-area SR of the display panel 50. The data driver 20 may be arranged on the display panel 50 in the form of an IC. For example, the data driver 20 may be a data driving IC that is configured to generate a data signal.

The display circuit board 30 may be attached to an end portion of the sub-area SR of the display panel 50. The display circuit board 30 may be electrically connected to the data driver 20, etc. via a pad of the sub-area SR of the display panel 50.

FIG. 5 is a plan view schematically showing a display panel of the display device of FIGS. 1A and 2A.

Referring to FIG. 5, the display panel 50 may include the substrate 100. Various components of the display panel 50 may be arranged on the substrate 100.

The substrate 100 may include glass, ceramic, metal, and/or polymer resin. The substrate 100 may include, for example, polymer resin, such as polyethersulfone, polyacrylate, polyetherimide, polyethylene naphthalate, polyethylene terephthalate, polyphenylene sulfide, polyarylate, polyimide, polycarbonate, and/or cellulose acetate propionate. The substrate 100 may have a multilayer structure including two layers including polymer resin and an inorganic layer arranged between the two layers. Alternatively, the substrate 100 may have a structure in which layers including polymer resin and inorganic layers are alternately stacked. The inorganic layer may include, for example, silicon oxide, silicon nitride, and/or silicon oxynitride.

Sub-pixels may be arranged in the display area DA, and the display area DA may provide an image by using light emitted from the sub-pixels. Each of the sub-pixels may include a light-emitting diode LED, and the light-emitting diode LED may be electrically connected to a sub-pixel circuit PC. The sub-pixel circuit PC and the light-emitting diode LED may be arranged in the display area DA. For convenience, FIG. 5 illustrates that the sub-pixel circuit PC and the light-emitting diode LED are arranged side by side, but in practice, the sub-pixel circuit PC and the light-emitting diode LED may at least partially overlap each other. For example, the light-emitting diode LED may be arranged on the sub-pixel circuit PC.

A gate driving circuit, a pad 54, a first power supply wiring 55, and a second power supply wiring 56 may be arranged in the peripheral area PA. The gate driving circuit may include, for example, a first scan driving circuit 51, a second scan driving circuit 52, and/or an emission control driving circuit 53.

The first scan driving circuit 51 may be configured to provide a scan signal to the sub-pixel circuit PC via a scan line SL. The second scan driving circuit 52 may be arranged at an opposite side to the first scan driving circuit 51 with the display area DA therebetween. Some of the sub-pixel circuits PC arranged in the display area DA may be electrically connected to the first scan driving circuit 51, while the others may be connected to the second scan driving circuit 52. In some cases, the second scan driving circuit 52 may be omitted.

Similar to the first scan driving circuit 51, the emission control driving circuit 53 may be arranged on one side of the display area DA. The emission control driving circuit 53 may be configured to provide an emission control signal to a sub-pixel via an emission control line EL. FIG. 5 illustrates that the emission control driving circuit 53 is arranged on opposite sides of the display area DA from the second scan driving circuit 52 and is embedded in the first scan driving circuit 51, but the present disclosure is not limited thereto. For example, the display panel 50 may include the emission control driving circuit 53 arranged on one side of the display area DA. Alternatively, the first scan driving circuit 51 may be arranged on one side of the display area DA, and the emission control driving circuit 53 may be arranged on the other side of the display area DA.

The pad 54 may be arranged in the peripheral area PA of the substrate 100. The pad 54 may be exposed without being covered by an insulating layer and may be electrically connected to the display circuit board 30. A pad 34 of the display circuit board 30 may be electrically connected to the pad 54 of the display panel 50.

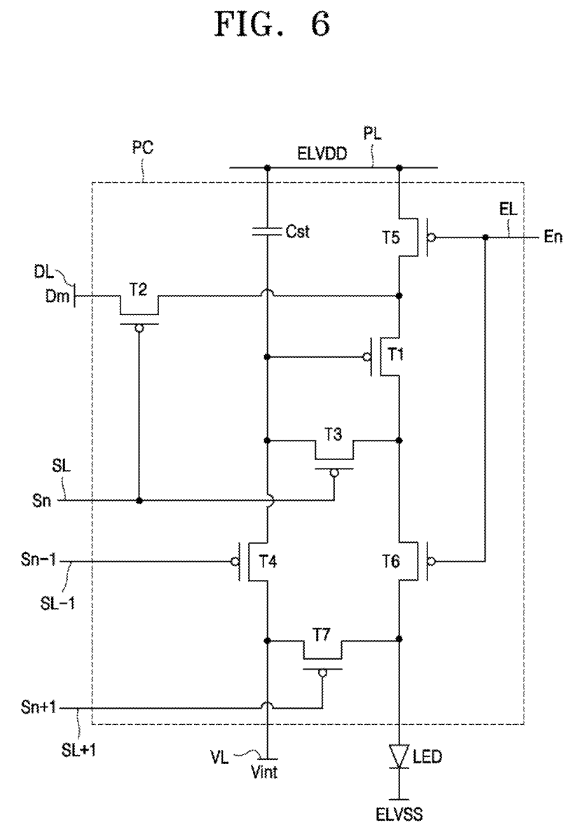

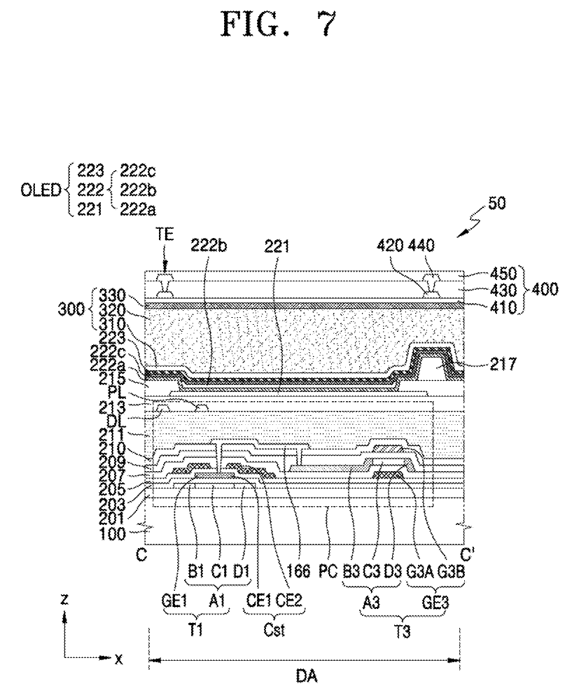

The display circuit board 30 transmits a signal of a controller or power to the display panel 50. A control signal generated by the controller may be transmitted to the gate driving circuit via the display circuit board 30. In addition, the controller may provide a first power voltage ELVDD (see FIG. 6) and a second power voltage ELVSS (see FIG. 6) to the first power supply wiring 55 and the second power supply wiring 56. The first power voltage ELVDD (hereinafter, referred to as a driving voltage) may be provided to each of the sub-pixel circuits PC via a driving voltage line PL connected to the first power supply wiring 55, and the second power voltage ELVSS (hereinafter, referred to as a common voltage) may be provided to a common electrode of the light-emitting diode LED connected to the second power supply wiring 56. The first power supply wiring 55 may extend in the first direction (the x direction). The second power supply wiring 56 may have a loop shape with one side open and may be around (e.g., may partially surround) the display area DA.

The data signal of the data driver 20 may be transmitted to the sub-pixel circuit PC via a data line DL electrically connected to an input line IL connected to the data driver 20.

FIG. 6 is an equivalent circuit diagram of one sub-pixel arranged in a display area of a display panel of FIG. 5.

Referring to FIG. 6, the light-emitting diode LED may be electrically connected to the sub-pixel circuit PC.

The sub-pixel circuit PC may include a first thin-film transistor T1, a second thin-film transistor T2, a third thin-film transistor T3, a fourth thin-film transistor T4, a fifth thin-film transistor T5, a sixth thin-film transistor T6, a seventh thin-film transistor T7, and a storage capacitor Cst.

The second thin-film transistor T2, as a switching thin-film transistor, is connected to the scan line SL and the data line DL, and may be configured to transmit, to the first thin-film transistor T1, a data voltage (or a data signal) Dm input from the data line DL based on a switching voltage (or a scan signal) Sn input from the scan line SL. The storage capacitor Cst is connected to the first thin-film transistor T1 and the driving voltage line PL, and may be configured to store a voltage corresponding to a difference between a voltage received from the second thin-film transistor T2 and the first power voltage ELVDD supplied to the driving voltage line PL.

The first thin-film transistor T1, as a driving thin-film transistor, is connected to the driving voltage line PL and the storage capacitor Cst, and may be configured to control a driving current flowing from the driving voltage line PL to the light-emitting diode LED according to a voltage value stored in the storage capacitor Cst. The light-emitting diode LED may emit light having a certain luminance according to the driving current. A second electrode (for example, a cathode) of the light-emitting diode LED may receive the second power voltage ELVSS.

The third thin-film transistor T3 is a compensation thin-film transistor, and a gate electrode of the third thin-film transistor T3 may be connected to the scan line SL. A source electrode (or a drain electrode) of the third thin-film transistor T3 may be connected to a drain electrode (or a source electrode) of the first thin-film transistor T1 and concurrently (e.g., simultaneously) connected to a first electrode of the light-emitting diode LED via the sixth thin-film transistor T6. The drain electrode (or the source electrode) of the third thin-film transistor T3 may be connected to any one electrode of the storage capacitor Cst, a source electrode (or a drain electrode) of the fourth thin-film transistor T4, and a gate electrode of the first thin-film transistor T1. The third thin-film transistor T3 is turned on according to a scan signal Sn, which is received via the scan line SL, to connect the gate electrode and the drain electrode of the first thin-film transistor T1 to each other, making the first thin-film transistor T1 a diode-connected transistor.

The fourth thin-film transistor T4 is an initialization thin-film transistor and a gate electrode thereof may be connected to a previous scan line SL-1. The drain electrode (or the source electrode) of the fourth thin-film transistor T4 may be connected to an initialization voltage line VL. The source electrode (or the drain electrode) of the fourth thin-film transistor T4 may be connected to any one electrode of the storage capacitor Cst, the drain electrode (or the source electrode) of the third thin-film transistor T3, and the gate electrode of the first thin-film transistor T1. The fourth thin-film transistor T4 may be turned on according to a previous scan signal Sn-1 received via the previous scan line SL-1 to transmit an initialization voltage Vint to the gate electrode of the first thin-film transistor T1 and perform an initialization operation of initializing a voltage of the gate electrode of the first thin-film transistor T1.

The fifth thin-film transistor T5 is an operation control thin-film transistor and a gate electrode thereof may be connected to the emission control line EL. A source electrode (or a drain electrode) of the fifth thin-film transistor T5 may be connected to the driving voltage line PL. The drain electrode (or the source electrode) of the fifth thin-film transistor T5 is connected to the source electrode (or the drain electrode) of the first thin-film transistor T1 and a drain electrode (or a source electrode) of the second thin-film transistor T2.

The sixth thin-film transistor T6 is an emission control thin-film transistor and a gate electrode thereof may be connected to the emission control line EL. A source electrode (or a drain electrode) of the sixth thin-film transistor T6 may be connected to the drain electrode (or the source electrode) of the first thin-film transistor T1 and the source electrode (or the drain electrode) of the third thin-film transistor T3. The drain electrode (or the source electrode) of the sixth thin-film transistor T6 may be electrically connected to the first electrode of the light-emitting diode LED. The fifth thin-film transistor T5 and the sixth thin-film transistor T6 is turned on at the same time according to an emission control signal En received via the emission control line EL, such that the first power voltage ELVDD is transmitted to the light-emitting diode LED, and a driving current flows through the light-emitting diode LED.

The seventh thin-film transistor T7 may be an initialization thin-film transistor configured to initialize the first electrode of the light-emitting diode LED. A gate electrode of the seventh thin-film transistor T7 may be connected to a subsequent scan line SL+1. A source electrode (or a drain electrode) of the seventh thin-film transistor T7 may be connected to the first electrode of the light-emitting diode LED. The drain electrode (or the source electrode) of the seventh thin-film transistor T7 may be connected to the initialization voltage line VL. The seventh thin-film transistor T7 may be turned on according to a subsequent scan signal Sn+1 received via the subsequent scan line SL+1 to initialize the first electrode of the light-emitting diode LED.

FIG. 6 illustrates a case where the fourth thin-film transistor T4 and the seventh thin-film transistor T7 may be respectively connected to the previous scan line SL-1 and the subsequent scan line SL+1, but in one or more other embodiments, both the fourth thin-film transistor T4 and the seventh thin-film transistor T7 may be connected to the previous scan line SL-1 and driven according to the previous scan signal Sn-1.

The other electrode of the storage capacitor Cst may be connected to the driving voltage line PL. Any one electrode of the storage capacitor Cst may be connected to the gate electrode of the first thin-film transistor T1, the drain electrode (or the source electrode) of the third thin-film transistor T3, and the source electrode (or the drain electrode) of the fourth thin-film transistor T4.

The second electrode (for example, a cathode) of the light-emitting diode LED receives the second power voltage ELVSS. The light-emitting diode LED receives a driving current from the first thin-film transistor T1 and emits light.

The light-emitting diode LED may be an organic light-emitting diode (OLED) including an organic material as a light-emitting material. In one or more other embodiments, the light-emitting diode LED may be an inorganic light-emitting diode including an inorganic material. The inorganic light-emitting diode may include a PN junction diode including inorganic semiconductor-based materials. When a voltage is applied to a PN junction diode in a forward direction, holes and electrons are injected, and energy generated due to recombination of the holes and the electrons is converted into light energy so that light of a certain color is emitted. The inorganic light-emitting diode may have a width of several to hundreds of micrometers, or several to hundreds of nanometers. In one or more embodiments, the light-emitting diode LED may include a quantum dot light-emitting diode. As described above, an emission layer of the light-emitting diode LED may include an organic material, inorganic material, quantum dots, both an organic material and a quantum dot, or both an inorganic material and quantum dots. Hereinafter, for convenience of explanation, a case where the light-emitting diode LED includes an organic light-emitting diode (OLED) is described.

FIG. 6 illustrates that the sub-pixel circuit PC includes seven transistors and one capacitor, but in one or more other embodiments, the sub-pixel circuit PC may include two or more transistors and two or more capacitors. In addition, a circuit design of the sub-pixel circuit PC is not limited to that shown in FIG. 6 and may be modified in various ways.

The first to seventh thin-film transistors T1, T2, T3, T4, T5, T6, and T7 may be transistors of various types. In one or more embodiments, as shown in FIG. 6, the first to seventh thin-film transistors T1, T2, T3, T4, T5, T6, and T7 may each be a p-channel metal-oxide-semiconductor field-effect transistor (MOSFET) (PMOS). In one or more other embodiments, at least one of the first to seventh thin-film transistors T1, T2, T3, T4, T5, T6, and T7 may be a PMOS, while the others may each be an n-channel MOSFET (NMOS). In one or more other embodiments, the first to seventh thin-film transistors T1, T2, T3, T4, T5, T6, and T7 may each be an NMOS transistor. Positions of sources and drains may be swapped depending on the type (a p-type or an n-type) of transistor.

The first to seventh thin-film transistors T1, T2, T3, T4, T5, T6, and T7 shown in FIG. 6 may each be a transistor having a low-temperature polycrystalline silicon (LTPS) semiconductor layer. In this case, the first to seventh thin-film transistors T1, T2, T3, T4, T5, T6, and T7 are not limited to the above, wherein at least one of the first to seventh thin-film transistors T1, T2, T3, T4, T5, T6, and T7 may be a transistor having an LTPS semiconductor layer, and the others may each be a transistor having an oxide semiconductor layer. Alternatively, the first to seventh thin-film transistors T1, T2, T3, T4, T5, T6, and T7 may each be a transistor having an oxide semiconductor layer.

FIG. 7 is a cross-sectional view schematically illustrating a portion of the display area of the display panel of FIG. 5. FIG. 7 is a cross-sectional view taken along the line C-C' of FIG. 5.

Referring to FIG. 7, the sub-pixel circuit PC and a light-emitting diode, for example, an organic light-emitting diode OLED, arranged in the display area DA of the display panel 50 are shown.

The substrate 100 may include glass, ceramic, metal, and/or polymer resin. In one or more embodiments, the substrate 100 may have a structure in which a base layer including polymer resin and a barrier layer including an inorganic insulating material such as silicon oxide or silicon nitride are alternately stacked. When the substrate 100 includes a structure of a stack of a base layer including polymer resin and a barrier layer including an inorganic insulating material, the flexibility of the electronic device 1 is improved, and thus, the foldable electronic device 1 may be provided.

The inorganic insulating material may include silicon oxide, silicon nitride, and/or silicon oxynitride.

The substrate 100 may include polymer resin, such as polyethersulfone, polyacrylate, polyetherimide, polyethylene naphthalate, polyethylene terephthalate, polyphenylene sulfide, polyarylate, polyimide, polycarbonate, and/or cellulose acetate propionate. Hereinafter, for convenience of explanation, a case where the substrate 100 includes a glass material is described in detail.

The sub-pixel circuit PC may be formed (e.g., located) on the substrate 100, and the light-emitting diode, for example, the organic light-emitting diode OLED, may be formed on the sub-pixel circuit PC.

Before the sub-pixel circuit PC is formed on the substrate 100, a buffer layer 201, which is formed to prevent penetration of impurities into the sub-pixel circuit PC, may be formed on the substrate 100. The buffer layer 201 may include an inorganic insulating material such as silicon nitride, silicon oxynitride, and/or silicon oxide, and may have a single-layered or multilayer structure including the inorganic insulating material.

The sub-pixel circuit PC may include a plurality of thin-film transistors and a storage capacitor, as described above with reference to FIG. 6. In this regard, FIG. 7 illustrates the first thin-film transistor T1, the third thin-film transistor T3, and the storage capacitor Cst.

The first thin-film transistor T1 may include a semiconductor layer (hereinafter, referred to as a first semiconductor layer) A1 on the buffer layer 201 and a gate electrode (hereinafter, referred to as a first gate electrode) GE1 overlapping a channel area C1 of the first semiconductor layer A1. The first semiconductor layer A1 may include a silicon-based semiconductor material, for example, polysilicon. The first semiconductor layer A1 may include the channel area C1, and a first area B1 and a second area D1 arranged at opposite sides of the channel area C1. The first area B1 and the second area D1 include a higher concentration of impurities than the channel area C1, wherein any one of the first area B1 and the second area D1 may correspond to a source area, while the other one may correspond to a drain area.

A first gate insulating layer 203 may be arranged between the first semiconductor layer A1 and the first gate electrode GE1 and on the buffer layer 201. The first gate insulating layer 203 may include an inorganic insulating material such as silicon oxide, silicon nitride, and/or silicon oxynitride, and may have a single-layered or multilayer structure including the inorganic insulating material.

The first gate electrode GE1 may include a conductive material including molybdenum (Mo), aluminum (Al), copper (Cu), and/or titanium (Ti), and may have a single-layered or multilayer structure including the above-described material.

The storage capacitor Cst may include a lower electrode CE1 and an upper electrode CE2, which overlap each other in a third direction (e.g., z-direction). In one or more embodiments, the lower electrode CE1 of the storage capacitor Cst may include the first gate electrode GE1. In other words, the first gate electrode GE1 may include the lower electrode CE1 of the storage capacitor Cst. For example, the first gate electrode GE1 and the lower electrode CE1 of the storage capacitor Cst may be integrally formed as a single body.

A first interlayer insulating layer 205 may be arranged between the lower electrode CE1 and the upper electrode CE2 of the storage capacitor Cst and on the first gate insulating layer 203. The first interlayer insulating layer 205 may include an inorganic insulating material such as silicon oxide, silicon nitride, and/or silicon oxynitride, and may have a single-layered or multilayer structure including the inorganic insulating material.

The upper electrode CE2 of the storage capacitor Cst may include a low-resistance conductive material such as molybdenum (Mo), aluminum (Al), copper (Cu), and/or titanium (Ti), and may have a single-layered or multilayer structure including the above-described material.

A second interlayer insulating layer 207 may be arranged on the storage capacitor Cst and on the first interlayer insulating layer 205. The second interlayer insulating layer 207 may include an inorganic insulating material such as silicon oxide, silicon nitride, and/or silicon oxynitride, and may have a single-layered or multilayer structure including the inorganic insulating material.

A semiconductor layer (hereinafter, referred to as a third semiconductor layer) A3 of the third thin-film transistor T3 may be arranged on the second interlayer insulating layer 207. The third semiconductor layer A3 may include a silicon-based semiconductor material, for example, polysilicon.

The third semiconductor layer A3 may include a channel area C3, and a first area B3 and a second area D3 arranged at opposite sides of the channel area C3. Any one of the first area B3 and the second area D3 may correspond to a source area, and the other one may correspond to a drain area.

The third thin-film transistor T3 may include a gate electrode (hereinafter, referred to as a third gate electrode) GE3 overlapping the channel area C3 of the third thin-film transistor T3 in the third direction (e.g., z-direction). The third gate electrode GE3 may have a dual gate structure including a lower gate electrode G3A arranged under the third semiconductor layer A3 and an upper gate electrode G3B arranged above the channel area C3.

The lower gate electrode G3A may be arranged on (e.g., at) the same layer (for example, the first interlayer insulating layer 205) as the upper electrode CE2 of the storage capacitor Cst. The lower gate electrode G3A may include the same material as the upper electrode CE2 of the storage capacitor Cst.

The upper gate electrode G3B may be arranged above the third semiconductor layer A3 with a second gate insulating layer 209 therebetween. The second gate insulating layer 209 may be on the second interlayer insulating layer 207 and may include an inorganic insulating material such as silicon oxide, silicon nitride, and/or silicon oxynitride, and may have a single-layered or multilayer structure including the inorganic insulating material.

A third interlayer insulating layer 210 may be arranged on the upper gate electrode G3B and on the second gate insulating layer 209. The third interlayer insulating layer 210 may include an inorganic insulating material such as silicon oxynitride, and may have a single-layered or multilayer structure including the inorganic insulating material.

FIG. 7 illustrates the first thin-film transistor T1 and the third thin-film transistor T3 from among a plurality of thin-film transistors as described with reference to FIG. 6, and illustrates that the first semiconductor layer A1 and the third semiconductor layer A3 are arranged on different layers, but the present disclosure is not limited thereto.

The second, fourth, fifth, sixth, and seventh thin-film transistors T2, T4, T5, T6, and T7 (see FIG. 6) described with reference to FIG. 6 may each have the same structure as the first thin-film transistor T1 described with reference to FIG. 7. For example, the second, fourth, fifth, sixth, and seventh thin-film transistors T2, T4, T5, T6, and T7 (see FIG. 6) may each include a semiconductor layer arranged on (e.g., at) the same layer as the first semiconductor layer A1 of the first thin-film transistor T1, and a gate electrode arranged on (e.g., at) the same layer as the first gate electrode GE1 of the first thin-film transistor T1. The semiconductor layers of the second, fourth, fifth, sixth, and seventh thin-film transistors T2, T4, T5, T6, and T7 (see FIG. 6) may be integrally connected to the first semiconductor layer A1.

The first thin-film transistor T1 and the third thin-film transistor T3 may be electrically connected to each other via a node connection line 166. The node connection line 166 may be arranged on the third interlayer insulating layer 210. One side of the node connection line 166 may be connected to the first gate electrode GE1 of the first thin-film transistor T1, and another side of the node connection line 166 may be connected to the third semiconductor layer A3 of the third thin-film transistor T3.

The node connection line 166 may include aluminum (Al), copper (Cu), and/or titanium (Ti), and may be formed as a single layer or a multilayer, each including the above-described material. For example, the node connection line 166 may have a three-layer structure of titanium layer/aluminum layer/titanium layer.

A first organic insulating layer 211 may be arranged on the node connection line 166 and on the third interlayer insulating layer 210. The first organic insulating layer 211 may include an organic insulating material. The organic insulating material may include acryl, benzocyclobutene (BCB), polyimide, and/or hexamethyldisiloxane (HMDSO).

The data line DL and the driving voltage line PL may be arranged on the first organic insulating layer 211 and may be covered with a second organic insulating layer 213 disposed on the first organic insulating layer 211. The data line DL and the driving voltage line PL may each include aluminum (Al), copper (Cu), and/or titanium (Ti), and may each be formed as a single layer or a multilayer each including the above-described material. For example, the data line DL and the driving voltage line PL may have a three-layer structure of titanium layer/aluminum layer/titanium layer.

The second organic insulating layer 213 may include an organic insulating material such as acryl, BCB, polyimide, and/or HMDSO. FIG. 7 illustrates that the data line DL and the driving voltage line PL are formed on the first organic insulating layer 211, but the present disclosure is not limited thereto. In one or more embodiments, one of the data line DL and the driving voltage line PL may be arranged on (e.g., at) the same layer, for example, the third interlayer insulating layer 210, as the node connection line 166.

The light-emitting diode, for example, the organic light-emitting diode OLED, may be arranged on the second organic insulating layer 213.

A first electrode 221 of the organic light-emitting diode OLED may include a reflective film including silver (Ag), magnesium (Mg), aluminum (Al), platinum (Pt), palladium (Pd), gold (Au), nickel (Ni), neodymium (Nd), iridium (Ir), chromium (Cr), and/or compounds or mixtures thereof. In one or more embodiments, the first electrode 221 may further include a conductive oxide layer arranged above and/or under the reflective film. The conductive oxide layer may include indium tin oxide (ITO), indium zinc oxide (IZO), zinc oxide (ZnO), indium oxide (In₂O₃), indium gallium oxide (IGO), and/or aluminum zinc oxide (AZO). In one or more embodiments, the first electrode 221 may have a three-layer structure of ITO layer/Ag layer/ITO layer.

A bank layer 215 may be arranged on the first electrode 221. The bank layer 215 may include an opening overlapping the first electrode 221 and cover an edge of the first electrode 221. The bank layer 215 may include an organic insulating material such as polyimide.

An intermediate layer 222 includes an emission layer 222b. The intermediate layer 222 may include a first functional layer 222a arranged under the emission layer 222b and/or a second functional layer 222c arranged above the emission layer 222b. The emission layer 222b may include a polymer or low-molecular-weight organic material that emits light of a certain color. The second functional layer 222c may include an electron transport layer (ETL) and/or an electron injection layer (EIL). The first functional layer 222a and the second functional layer 222c may include an organic material.

A second electrode 223 may include a conductive material having a low work function. For example, the second electrode 223 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), and/or an alloy thereof. Alternatively, the second electrode 223 may further include a layer including ITO, IZO, ZnO, and/or In₂O₃ on the (semi-)transparent layer including the above-described material.

The emission layer 222b may be formed in the display area DA to overlap the first electrode 221 via the opening in the bank layer 215. In contrast, the first functional layer 222a, the second functional layer 222c, and the second electrode 223 may entirely cover the display area DA.

A spacer 217 may be formed on the bank layer 215. The spacer 217 and the bank layer 215 may be formed together in the same process or may be formed individually in separate processes. In one or more embodiments, the spacer 217 may include an organic insulating material such as polyimide. Alternatively, the bank layer 215 may include an organic insulating material including a light-blocking dye, and a spacer 217 may include an organic insulating material such as polyimide.

The organic light-emitting diode OLED may be covered with an encapsulation layer 300. The encapsulation layer 300 may include at least one organic encapsulation layer and at least one inorganic encapsulation layer. In one or more embodiments, FIG. 7 illustrates that the encapsulation layer 300 includes first and second inorganic encapsulation layers 310 and 330 and an organic encapsulation layer 320 arranged therebetween.

The first inorganic encapsulation layer 310 and the second inorganic encapsulation layer 330 may include one or more inorganic materials from among aluminum oxide, titanium oxide, tantalum oxide, hafnium oxide, zinc oxide, silicon oxide, silicon nitride, and silicon oxynitride. The first inorganic encapsulation layer 310 and the second inorganic encapsulation layer 330 may each be a single layer or a multilayer, each including the above-described material. The organic encapsulation layer 320 may include a polymer-based material. The polymer-based material may include an acrylic-based resin, an epoxy-based resin, polyimide, polyethylene, etc. In one or more embodiments, the organic encapsulation layer 320 may include acrylate.

Thicknesses of the first inorganic encapsulation layer 310 and the second inorganic encapsulation layer 330 may be different from each other. The thickness of the first inorganic encapsulation layer 310 may be greater than the thickness of the second inorganic encapsulation layer 330. Alternatively, the thickness of the second inorganic encapsulation layer 330 may be greater than the thickness of the first inorganic encapsulation layer 310, or the thicknesses of the first inorganic encapsulation layer 310 and the second inorganic encapsulation layer 330 may be identical to (or substantially the same as) each other.

An input sensing layer 400 may be arranged on the encapsulation layer 300. The input sensing layer 400 may include touch electrodes TE arranged in the display area DA and at least one touch insulating layer. In this regard, FIG. 7 illustrates that the input sensing layer 400 includes a first touch insulating layer 410 on the second inorganic encapsulation layer 330, a first conductive line 420 on the first touch insulating layer 410, a second touch insulating layer 430 on the first conductive line 420 and the first touch insulating layer 410, a second conductive line 440 on the second touch insulating layer 430, and a third touch insulating layer 450 on the second conductive line 440 and the second touch insulating layer 430.

Each of the first touch insulating layer 410, the second touch insulating layer 430, and the third touch insulating layer 450 may include an inorganic insulating material and/or an organic insulating material. In one or more embodiments, the first touch insulating layer 410 and the second touch insulating layer 430 may each include an inorganic insulating material such as silicon oxide, silicon nitride, and/or silicon oxynitride, and the third touch insulating layer 450 may include an organic insulating material.

A touch electrode TE of the input sensing layer 400 may include a structure in which the first conductive line 420 and the second conductive line 440 are connected to each other. Alternatively, the touch electrode TE may include one of the first conductive line 420 and the second conductive line 440, and in this case, the second touch insulating layer 430 may be omitted.

Each of the first conductive line 420 and the second conductive line 440 may include aluminum (Al), copper (Cu), and/or titanium (Ti), and may be formed as a single layer or a multilayer, each including the above-described material. For example, each of the first conductive line 420 and the second conductive line 440 may have a three-layer structure of titanium layer/aluminum layer/titanium layer.

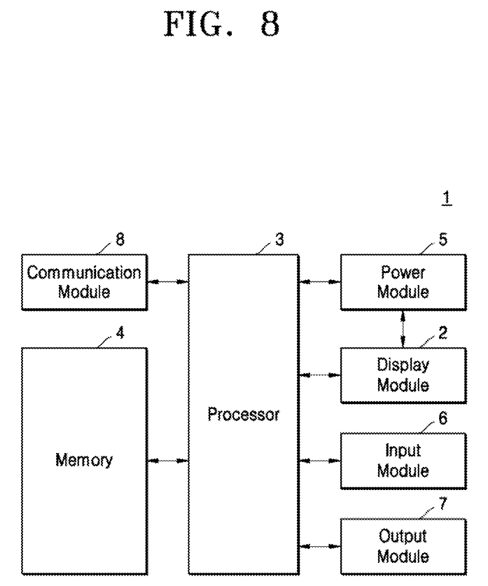

FIG. 8 is a block diagram of an electronic device according to one or more embodiments.

Referring to FIG. 8, the electronic device 1 according to one or more embodiments may include: a display module 2 including a display device; a processor 3; a memory 4; and a power module 5.

The processor 3 may include at least one of a central processing unit (CPU), an application processor (AP), a graphics processing unit (GPU), a communication processor (CP), an image signal processor (ISP), and a controller. In one or more embodiments, the processor 3 may be provided as two or more separate units from a functional or structural perspective. For example, the processor 3 may include a main processor in the form of a first driving chip including a CPU and an auxiliary processor in the form of a second driving chip including a controller, wherein the auxiliary processor receives an image signal from the main processor and processes the image signal to satisfy interface specifications of the display module 2.

The memory 4 may include at least one of non-volatile memory and volatile memory. The memory 4 may store data information required by the processor 3 or the display module 2 to operate. When the processor 3 executes an application stored in the memory 4, an image data signal and/or an input control signal may be transmitted to the display module 2, and the display module 2 may process the received signal and output image information on a display screen.

The power module 5 may include a power supply module, such as a power adapter or a battery apparatus, and a power conversion module that converts power supplied by the power supply module and generates power required by the electronic device 1 to operate. Power conversion by the power conversion module may include DC-DC conversion, AC-DC conversion, and DC-AC conversion, but is not limited thereto.

The electronic device 1 may further include an input module 6, a non-image output module (e.g., an output module) 7, and/or a communication module 8.

The input module 6 may provide input information to the processor 3 and/or the display module 2. The input module 6 may include a physical button, a keyboard, a microphone, and various sensor modules. Examples of a sensor module may include not only a touch sensor, a pressure sensor, a distance sensor, a location sensor, a digitizer, a motion recognition sensor, a camera sensor, a light-receiving sensor, a photoelectric conversion sensor, and a temperature sensor, but also a biometric sensor such as a blood pressure sensor, a blood glucose sensor, an electrocardiogram sensor, and/or a heart rate sensor.

The non-image output module 7 may receive information other than an image received from the processor 3 and provide the information to a user. Examples of the non-image output module 7 may be an audio module, a haptic module, and a light-emitting module, and may include other functional modules (for example, a cooling module of a refrigerator) that are unique to the electronic device 1.

The communication module 8 may be configured to transmit and receive information between the electronic device 1 and an external apparatus and may include a receiver and/or a transmitter. The communication module 8 may include various wireless communication modules such as a mobile communication module, a Wi-Fi module, and a Bluetooth module, or various wired communication modules.

At least one of the components of the electronic device 1 may be included in the display device according to the above-described embodiments. In addition, some individual modules functionally included within one module may be included in the display device, and other individual modules may be provided separately from the display device. For example, the display device may include the display module 2, and the processor 3, the memory 4, and the power module 5 may be provided in the form of other apparatuses within the electronic device 1 rather than the display device. In another example, the power module 5 may be provided within the display device and may supply power to the processor 3 and the memory 4, which are provided within the electronic device 1 rather than the display device. However, these examples are not limited thereto.

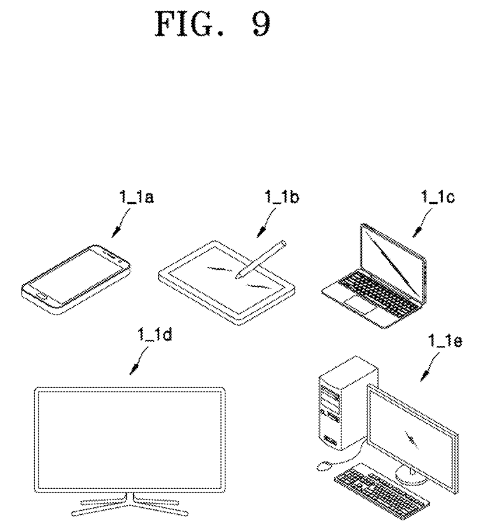

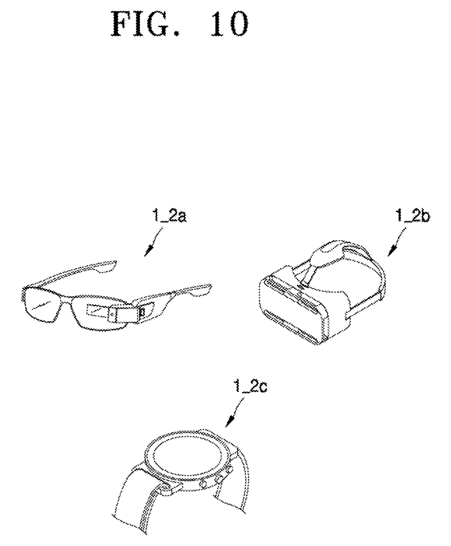

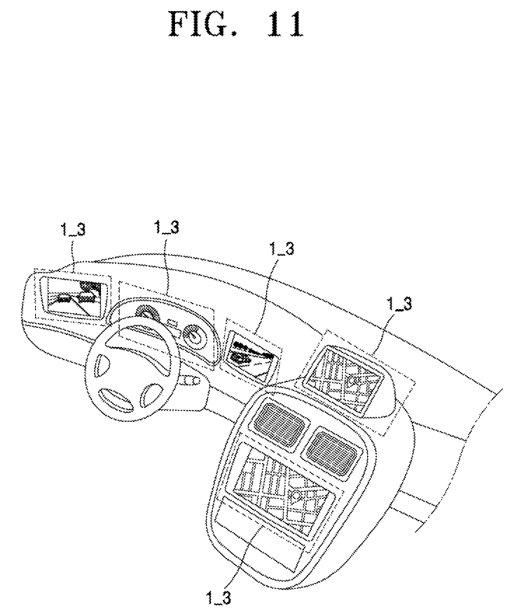

FIGS. 9 – 11 are schematic views of electronic devices according to one or more embodiments. FIGS. 9 – 11 show examples of various electronic devices to which a display device according to one or more embodiments is applied.

FIG. 9 shows, as examples of an electronic device, a smartphone 1_1a, a tablet PC 1_1b, a laptop 1_1c, a TV 1_1d, and a desk monitor 1_1e.

The smartphone 1_1a may include an input module, such as a touch sensor, and a communication module, in addition to the display module 2. The smartphone 1_1a may process information received via the communication module or other input modules and display the information via the display module of the display device.

Similar to the smartphone 1_1a, the tablet PC 1_1b, the laptop 1_1c, the TV 1_1d, and the desk monitor 1_1e may include a display module and an input module, and in some cases, may further include a communication module.

FIG. 10 shows a case where an electronic device including a display module is applied to a wearable electronic device. The wearable electronic device may include smart glasses 1_2a, a head-mounted display 1_2b, and a smart watch 1_2c.

The smart glasses 1_2a and the head-mounted display 1_2b may each include a display module that displays a display image; and a reflector that reflects a displayed display screen and provides it to a user's eyes, thereby providing a virtual reality or augmented reality screen to the user.

The smart watch 1_2c may include a biometric sensor as an input apparatus and may provide biometric information recognized by the biometric sensor to a user via a display module.

FIG. 11 shows a case where an electronic device including a display module is applied to a vehicle. For example, an electronic device 1_3 may be applied to an instrument panel of a vehicle or a center fascia, or may be applied to a center information display (CID) arranged on the dashboard of a vehicle or a room mirror display in place of side-view mirrors.

In one or more embodiments, an electronic device to which a display device is applied according to one or more embodiments may include not only apparatuses for screen displays, such as billboards, electronic billboards, and game device, but also various home appliances that display information via a display module, such as refrigerators, washing machines, dryers, air conditioners, and/or robot vacuums. In addition, when a display module has a function of transmitting light, the display module may be applied to an electronic device such as a smart window or a transparent display device that displays a background and a display image together. The types of electronic devices according to one or more embodiments are not limited to the examples provided above, and the application of other various electronic devices that are not provided as examples is also possible.

The display device and the electronic device according to one or more embodiments of the present disclosure may provide clear images.

The display device and the electronic device according to one or more embodiments of the present disclosure may be freely folded.

The display device and the electronic device according to one or more embodiments of the present disclosure may each have a reduced thickness.

The display device and the electronic device according to one or more embodiments of the present disclosure may protect the display panel from an external impact and/or foreign materials.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the claims and their equivalents.

What is claimed is:

1. A display device comprising:
a display panel; and
a cover member on the display panel,
wherein the cover member comprises:
a first layer on the display panel;
a second layer comprising a base layer and an anti-fingerprint layer on a side surface of the base layer, the base layer comprising a resin and covering the first layer; and
a third layer on the second layer.

2. The display device of claim 1, wherein the cover member further comprises a light blocking layer on a surface of the base layer facing the display panel.

3. The display device of claim 2, wherein the light blocking layer is further on at least a portion of a surface of the first layer facing the display panel.

4. The display device of claim 1, wherein the first layer comprises glass.

5. The display device of claim 1, wherein the second layer further comprises a hard coating layer between the anti-fingerprint layer and the base layer.

6. The display device of claim 5, wherein a thickness of the hard coating layer is within a range of at least about 5 μm but not more than about 15 μm.

7. The display device of claim 1, wherein the second layer further comprises a bonding layer between the anti-fingerprint layer and the base layer.

8. The display device of claim 1, wherein the cover member further comprises an adhesive layer between the second layer and the third layer.

9. The display device of claim 1, wherein a thickness of the anti-fingerprint layer is within a range of at least about 10 nm but not more than about 40 nm.

10. The display device of claim 1, wherein the anti-fingerprint layer is between the second layer and the third layer.

11. The display device of claim 1, wherein a refractive index of the first layer and a refractive index of the base layer are same as each other.

12. A display device comprising:
a display panel; and
a cover member on the display panel,
wherein the cover member comprises:
a first layer on the display panel;
a second layer covering the first layer is, wherein a first contact angle of a surface of the second layer facing the display panel and a second contact angle of a side surface of the second layer are different from each other; and
a third layer on the second layer.

13. The display device of claim 12, wherein the first contact angle is less than the second contact angle.

14. The display device of claim 12, wherein the cover member further comprises a light blocking layer on at least one of a surface of the first layer or the surface of the second layer facing the display panel.

15. The display device of claim 12, wherein the first layer comprises glass.

16. The display device of claim 12, wherein the cover member further comprises an adhesive layer between the second layer and the third layer.

17. An electronic device comprising:
a display device; and
a memory connected to the display device,
wherein the display device comprises:
a display panel; and
a cover member on the display panel,
wherein the cover member comprises:
a first layer on the display panel;
a second layer comprising a base layer and an anti-fingerprint layer on a side surface of the base layer, the base layer comprising a resin and covering the first layer; and
a third layer on the second layer.

18. The electronic device of claim 17, wherein the cover member further comprises a light blocking layer on a surface of the base layer facing the display panel.

19. The electronic device of claim 17, wherein the second layer further comprises a hard coating layer between the anti-fingerprint layer and the base layer.

20. The electronic device of claim 17, wherein the second layer further comprises a bonding layer between the anti-fingerprint layer and the base layer.
